(19) United States
(12) Patent Application Publication
(10) Pub. No.: US 2025/0125115 A1
(43) Pub. Date: Apr. 17, 2025

(54) MULTI-BEAM SYSTEM AND MULTI-BEAM FORMING UNIT WITH REDUCED SENSITIVITY TO SECONDARY RADIATION

(71) Applicant: Carl Zeiss MultiSEM GmbH, Oberkochen (DE)

(72) Inventors: Christian Veit, Leinfelden-Echterdingen (DE); Marcus Kaestner, Syrgenstein- Staufen (DE); Georg Kurij, Ulm (DE)

(21) Appl. No.: 18/988,751

(22) Filed: Dec. 19, 2024

Related U.S. Application Data
(63) Continuation of application No. PCT/EP2023/025280, filed on Jun. 13, 2023.

(30) Foreign Application Priority Data
Jun. 23, 2022 (DE) 10 2022 206 314.7

(51) Int. Cl. H01J 37/09; H01J 37/26

(52) U.S. Cl. CPC H01J 37/09; H01J 37/265; H01J 2237/0453

(57) ABSTRACT

A multi-beam charged particle beam system includes a multi-beam forming unit with a lower sensitivity to secondary electrons, scattered charge particles and x-ray radiation. Thereby, a plurality of primary charged particle beamlets can be generated with higher precision and with a longer lifetime of a multi-beam forming unit. The system and method are applicable for an inspection of samples, for example for wafer or mask inspection.

### CROSS-REFERENCE TO RELATED APPLICATIONS

The present application is a continuation of, and claims benefit under 35 USC 120 to, international application No. PCT/EP2023/025280, filed Jun. 13, 2023, which claims benefit under 35 USC 119 of German Application No. 10 2022 206 314.7, filed Jun. 23, 2022. The entire disclosure of each of these applications is incorporated by reference herein.

### FIELD

The disclosure relates to a multi-beam forming unit with an array of micro-lenses or multi-pole elements of a multi-beam charged particle imaging system.

### BACKGROUND

WO 2005/024881 A2 discloses an electron microscope system which operates with a multiplicity of electron beamlets for the parallel scanning of an object to be inspected with a plurality of electron beamlets. Multiple beamlets for a multi-beam, charged particle microscope are generated in a multi-beam generating unit. The plurality of electron beamlets is generated by directing a primary electron beam onto the multi-beam generating unit. The multi-beam forming unit comprises a first multi-aperture element or filter plate, which has a multiplicity of openings. One portion of the electrons of the electron beam is incident onto the filter plate and is absorbed there, and another portion of the beam transmits the aperture openings of the filter plate. An electron beamlet is formed whose cross section is defined by the cross section of the aperture opening. Furthermore, the multi-beam forming unit comprises further multi-aperture array elements which act as a lens, deflector or stigmator on each electron beamlet. Downstream of the multi-beam generating unit, further electron-optical elements are arranged to form focus spots of the electron beamlets on a surface of an object or sample. The primary electron beamlets trigger secondary electrons or backscattered electrons to emanate as secondary electron beamlets from the object, which are collected and imaged onto a detector. Each of the secondary beamlets is incident onto a separate detector element so that the secondary electron intensities detected therewith provide information relating to the sample at the location where the corresponding primary beamlet is incident onto the sample. The plurality of primary beamlets is scanned systematically over the surface of the sample and a microscopic image of the sample is generated like in scanning electron microscopes. The resolution of a scanning electron microscope is generally limited by the focus diameter of the primary beamlets incident on the object. Consequently, in multi-beam electron microscopy all the beamlets should form the same small focus points on the object.

It is understood that the system and method illustrated in WO 2005/024881 in detail with the example of electrons is very well applicable in general to charged particles. The present disclosure correspondingly has an object of proposing a charged particle beam system which operates with a multiplicity of charged particle beams and can be used to achieve a higher imaging performance, such as a better resolution and narrower range of resolution for each beamlet of the plurality of beamlets.

Multi-beam charged particle microscopes commonly use both micro-optical array elements and macroscopic elements in a charged particle projection system. The multi-beam generating units comprise elements for splitting, partially absorbing, and influencing a beam of charged particles. As a result, a plurality of beamlets of charged particles in a predefined raster configuration is generated. Multi-beam generating units comprise micro-optical elements, such as the filter plate and further multi-aperture elements such as micro-optical deflection elements or multi-pole array elements. These array-optical elements, for example a multi-pole or multi-stigmator array or a lens array are arranged downstream of filter plate. The array-optical elements are provided with a plurality of apertures, each provided with at least one electrode or coil for individually or jointly influencing each primary electron beamlet. A control architecture for the plurality of electrodes or coils of an array-optical element comprises several micro-electronic devices in parallel. The micro-electronic devices provide a plurality of predetermined voltages or currents to the plurality of electrodes or coils. It has been observed that during their operation, the performance of array-optical elements can be subject to drifts. The drifts in the performance of the array-optical element can have several reasons. Particular reasons can be residual charges and local damages, which can be generated during use of an array-optical element.

A first cause for the drift can be scattered or absorbed primary electrons. A second cause for the drift can be secondary electrons, which are generated for example at the filter plate. A third cause can be secondary radiation, comprising X-ray radiation. The electrons or secondary radiation can be absorbed or scattered in the apertures of an array-optical element and can be leading to a charging effect and a local change of a surface potential of an array-optical element. It has also been observed that secondary radiation can generate a damage to array-optical elements. Other effects can be an electron-facilitated contamination for example of the apertures of an array-optical element.

WO 2021/180365 A1 discloses certain features of multi-beam raster units such as multi-beam generating units and multi-beam deflector units of a multi-beam charged particle microscopes. The features include design, fabrication and adjustment of multi-beam raster units including apertures of specific shape and dimensions. The features can help enable multi-beam generation and multi-beam deflection or stigmation with higher precision.

WO 2005/024881 A2 discloses a particle-optical arrangement. The particle-optical arrangement comprises a charged-particle source for generating a beam of charged particles; a multi-aperture plate arranged in a beam path of the beam of charged particles, wherein the multi-aperture plate has a plurality of apertures formed therein in a predetermined first array pattern, wherein a plurality of charged-particle beamlets is formed from the beam of charged particles downstream of the multi-aperture plate, and wherein a plurality of beam spots is formed in an image plane of the apparatus by the plurality of beamlets, the plurality of beam spots being arranged in a second array pattern; and a particle-optical element for manipulating the beam of charged particles and/or the plurality of beamlets; wherein the first array pattern has a first pattern regularity in a first direction, and the second array pattern has a second pattern regularity in a second direction electron-optically corresponding to the first direction, and wherein the second regularity is higher than the first regularity.

US 2003/0209673 A1 relates to an electrooptic system array having a plurality of electron lenses. The electrooptic system array includes upper, middle, and lower electrodes arranged along the paths of a plurality of charged-particle beams, the upper, middle, and lower electrodes having pluralities of apertures on the paths of the plurality of charged-particle beams, an upper shield electrode which is interposed between the upper and middle electrodes and has a plurality of shields corresponding to the respective paths of the charged-particle beams, and a lower shield electrode which is interposed between the lower and middle electrodes and has a plurality of shields corresponding to the respective paths of the charged-particle beams.

### SUMMARY

The disclosure seeks to provide a multi-beam generator for a multi-beam charged particle system with a reduced sensitivity to charging effects and damages.

In embodiments, the disclosure provides an architecture of the charged-particle multi-beamlet generator of the multi-beam charged particle imaging system with reduced sensitivity to charging and damage by scattered charged particles, secondary electrons, and secondary radiation.

The disclosure provides a multi-beam charged particle imaging system and a method of operation of such a system. The multi-beam charged particle imaging systems comprises a charged-particle multi-beamlet generator for generating a plurality of primary charged particle beamlets. The multi-beam charged particle imaging system comprises an object irradiation system for focusing the plurality of primary charged particle beamlets on a surface of an object at a plurality of irradiation positions. During use, at each irradiation position on the surface of the object, secondary charged particles are generated, from which a plurality of secondary beamlets is formed. The multi-beam charged particle imaging systems comprises a secondary electron imaging system for focusing the plurality of secondary beamlets and for forming a plurality of focus points of the secondary beamlets in an image plane. The multi-beam charged particle imaging systems further comprises a detector, arranged in the image plane.

The multi-beam system comprises at least one active array-optical element and a control unit, configured for controlling the active array-optical element. The active array-optical element comprises a plurality of J apertures arranged in a raster configuration, which are configured for transmitting during use the first plurality of J primary charged particle beamlets through the active array-optical element. The raster configuration can be a hexagonal or a rectangular raster of J apertures, or the apertures can be arranged on a series of circular rings. An active array-optical element further comprises a plurality of electrodes comprising at least one electrode arranged in the circumference of each of the apertures. The active array-optical element can be a micro lens array with a single ring electrode at each of the plurality of aperture. The active array-optical element can also be a multi-pole array comprising a plurality of multi-pole elements with a number of K electrodes arranged in the circumference of each of the plurality of apertures, the number K of electrodes of each multi-pole element is two, four, six, eight or twelve.

In a first embodiment, the multi-beam system comprises a charged-particle multi-beamlet generator with a shielding multi-aperture plate. The shielding multi-aperture plate is arranged and configured to shield scattered charged particles and secondary radiation from hitting the active array-optical element. Secondary radiation can be x-ray radiation or secondary electrons, which lead to charging effects or damages at the active array-optical element. In an example, the shielding multi-aperture plate is arranged at the beam entrance side of an active array-optical element.

According to the first embodiment, the charged-particle multi-beamlet generator is configured for generating during use a plurality of J primary charged particle beamlets. The charged-particle multi-beamlet generator according to the disclosure can comprise a multi-beam forming unit with several array-optical elements, including a filter plate, a shielding multi-aperture plate and a first active array-optical element arranged in a propagation direction of the primary charged particles. The filter plate can comprise a plurality of first apertures, each with a first diameter D1 for generating during use the plurality of primary charged particle beamlets. During use, a primary charged particle beam impinges on the filter plate. Most primary charged particles are absorbed by the filter plate, and the primary charged particles passing the first apertures form the primary charged particle beamlets. The first active array-optical element comprises a plurality of third apertures, each with a third diameter D3. Near each third aperture, at least one electrode is arranged, each electrode is configured for individually influencing during use a primary charged particle beamlet. For example, the first active array optical element can comprise a plurality of ring electrodes, configured for independently generating electrostatic fields for focusing each of the primary charged particle beamlets. For example, the first active array optical element can comprise a plurality of multi-pole electrodes, configured for independently generating electrostatic fields for deflecting each of the primary charged particle beamlets or for focusing or for correcting aberrations.

During use, some primary charged particles are scattered at the filter plate and secondary electrons are generated. According to the first embodiment of the field, an opening or acceptance angle α for scattered charged particles or secondary electrons is reduced, and a charging or damaging of the first active array-optical element and any further downstream array-optical element is reduced. With the limited acceptance or opening angle α, the amount of scattered charged particles or secondary electrons that can enter the part of the multi-aperture stack below the filter plate is reduced. The reduction of the opening angle α is achieved by the shielding multi-aperture plate and the geometry of the arrangement of the shielding multi-aperture plate within the multi-beam forming unit. The shielding multi-aperture plate is arranged between the filter plate and the first active array-optical element. The shielding multi-aperture plate comprises a plurality of second apertures, each with a second diameter D2.

The filter plate has a first thickness L1. L1 can be kept at a low thickness below 20 μm, for example L1<=10 μm. The shielding multi-aperture plate has a third thickness L3 and is arranged at a distance L2 downstream of the filter plate. In an example, the distance L2, the thickness L1 and the second diameter D2 are defining the opening angle α with tan(α)=D2/(L1+L2). In an example, the distance L2, the thicknesses L1 and L3 and the second diameter D2 are defining the opening angle α with tan(α)=D2/(L1+L2+L3). According to a first example, distance L2, the thicknesses L1 or L3 and the second diameter D2 are selected such that a reduced opening angle is formed with tan((α)<0.3, such as tan((α)<0.25. The opening angle α is for example reduced by an increased distance L2 of for example L2>70 μm, for example 12=70 μm, L2=80 μm or L2=100 μm. The opening angle α is for example reduced by an increased thickness L3 of for example L3>70 μm, for example L3=100 μm or L3=120 μm. The opening angle α is for example reduced by a reduced diameter D2 of for example D2<1.3×D1, for example with D2<=40 μm, for example with D2=38 μm. In an example, at least one of a thickness or distance L2 or L3 is increased and the diameter D2 is reduced. In an example, the sum of the thicknesses and distance (L1+L2+L3) is selected to exceed 130 μm, for example (L1+L2+L3)=150 μm. In an example, the second diameter D2 is selected according to 1.1×D1<D2<1.3×D1.

The third apertures have a third diameter D3, and D2 is selected to be smaller than D3. For example, D3>1.6×D1, but D3 can even be selected with D3>=1.8×D1. Thereby, the active array-optical element is physically shielded by the shielding multi-aperture plate, and the number of secondary electrons or scattered primary charged particles impinging on the active array-optical element is even more effectively reduced. For example, D2 is selected in the interval 0.625×D3<=D2<=1.3×D1. For example, D2=1.3×D1 and D3=1.8×D1. For example, D2=1.2×D1 and D3=1.7×D1. For example, D2=1.1×D1 and D3=1.6×D1. For example, by achieving approximately a ratio of D2/D3<=0.75, the electrodes of active array-optical element are shielded by the shielding multi-aperture plate, and the number of secondary electrons or scattered primary charged particles impinging on the electrodes is effectively reduced.

The shielding multi-aperture plate may further be provided with at least an absorbing or metal layer, covering beam entry side of the shielding multi-aperture plate. According to an example, the absorbing or metal layer comprises a material of a group of materials comprising Molybdenum, Ruthenium, Rhodium, Palladium or Silver, Tungsten, Rhenium, Osmium, Iridium, Platinum, or Gold. Such a layer with a thickness of for example of about 1-2 μm can provide sufficient stopping power for scattered charged particles and secondary electrons. The thickness of such a layer can even be chosen thicker, for example larger than 10 μm or even larger than 20 μm, such that also x-ray radiation is efficiently shielded.

The shielding multi-aperture plate can further be configured for a reduction of scattered charged particles and secondary electrons. In a first example, at each of the second apertures of the shielding multi-aperture plate, at least one baffle for absorbing scattered charged particles and secondary electrons is formed. In a second example, the shielding multi-aperture plate is formed with a two-layer structure and each of the apertures with dimeter D2 is formed within a first layer with a thickness L3.1<L3. Thereby, scattering of charged particles or electrons inside the second apertures is reduced. In a third example, each of the second apertures of the shielding multi-aperture plate is formed with a conic shape such that the minimum aperture diameter D2 is formed at the bottom or beam exit side of the shielding multi-aperture plate. The absorbing layer may also cover the conic shaped aperture openings. In a fourth example, each of the second apertures of the shielding multi-aperture plate is formed with a conic shape such that the minimum aperture diameter D2 is formed at the top or beam entry side of the shielding multi-aperture plate. Thereby, a surface area at which contamination may grow is reduced.

In an example, the primary multi-beamlet-forming unit further comprises a further multi-aperture plate, formed as an absorber plate between the filter plate and the shielding multi-aperture plate. In an example, the diameter D4 of fourth apertures of the absorber plate is selected to be between the first diameter D1 and the third diameter D3, for example D4 is selected in a range 1.1×D1<D4<=D3.

The primary multi-beamlet-forming unit may comprise further multi-aperture plates, including further active array-optical multi-aperture plates and a terminating multi-aperture plate.

With the features according to the first embodiment, a lifetime of a primary multi-beamlet-forming unit can be increased. Furthermore, a charging or a damage of an active array-optical element due to scattered charged particles and secondary electrons is reduced. The impact of scattered charged particles and secondary electrons can be further reduced by the second embodiment of the disclosure. According to the second embodiment of the disclosure, a charged-particle multi-beamlet generator comprises a multi-beam forming unit with a filter plate and a first array optical element. The charged-particle multi-beamlet generator further comprises a first absorber plate with a plurality of fourth apertures with a diameter D4. The first absorber plate is arranged upstream of the filter plate. The filter plate comprises a plurality of first apertures, each with a first diameter D1 for generating during use the plurality of primary charged particle beamlets. In a first example, the diameter D4 of the fourth apertures is selected to be larger than the diameter D1 of the first apertures. During use, a primary charged particle beam first impinges on the first absorber plate. Most primary charged particles are absorbed by the first absorber plate, and the primary charged particles passing the fourth apertures form pre-shaped charged particle beamlets. The pre-shaped charged particle beamlets impinge impinging on the filter plate. A part of the pre-shaped charged particle beamlets is absorbed by the filter plate, and the primary charged particles passing the first apertures form the primary charged particle beamlets. The first active array-optical element comprises a plurality of third apertures, each with a third diameter D3. Near each third aperture, at least one electrode is arranged, each electrode is configured for individually influencing during use a primary charged particle beamlet. For example, the first active array optical element can comprise a plurality of ring electrodes, configured for independently generating electrostatic fields for focusing each of the primary charged particle beamlets. For example, the first active array optical element can comprise a plurality of multi-pole electrodes, configured for independently generating electrostatic fields for deflecting each of the primary charged particle beamlets or for focusing or for correcting aberrations.

With the absorber plate, the number of scattered charged particles and secondary electrons downstream of the filter plate can be effectively reduced. In an example, the diameter D4 of fourth apertures of the absorber plate is selected to be between the first diameter D1 and the third diameter D3, for example D4 is selected in a range 1.1×D1<D4<=D3.

By coating the top side, the bottom side or all surfaces of the absorber plate with a thick metal layer effectively shielding x-ray radiation (for example gold) or by using an all-metal absorber plate effectively shielding x-ray radiation, x-ray-induced radiation damage of the multi-aperture stack situated below the absorber plate can be further reduced. For example, the absorber plate can be coated with a conductive layer thicker than for example 10 μm or even 20 μm. For example, the absorber plate can be manufactured from a suitable metal or metal alloy, such as gold, tungsten or a gold alloy. In an example, the shielding multi-aperture plate comprises a material of a group of materials comprising Molybdenum, Ruthenium, Rhodium, Palladium or Silver, Tungsten, Rhenium, Osmium, Iridium, Platinum, or Gold. In an example, the conductive layer is formed from a material or material composition with lower atomic mass number. Thereby, the generation of secondary electrons is reduced. For example, the conductive layer is a metal layer, a graphite layer, or a doped semiconductor layer. Suitable metals with low atomic mass number at aluminum, manganese, copper or silver.

In an example, the primary multi-beamlet-forming unit further comprises a shielding multi-aperture plate with second apertures with a second diameter D2, the shielding multi-aperture plate having a third thickness 13; wherein 1.1×D1<D2<=1.5×D1. In an example, the primary multi-beamlet-forming unit comprises a second absorber plate between the filter plate and the shielding multi-aperture plate. In an example, the diameter D5 of fifth apertures of the absorber plate is selected to be between the first diameter D1 and the third diameter D3, for example D5 is selected in a range 1.1×D1<D5<=D3. The primary multi-beamlet-forming unit may comprise further multi-aperture plates, including further active array-optical multi-aperture plates and a terminating multi-aperture plate.

Within each of the shielding multi-aperture plate, the first or second absorber plate, each of the apertures can be provided with at least on baffle. Each of the apertures can be formed with a conic shape such that the minimum aperture diameter is formed at the bottom or beam exit side of the respective aperture. In an alternative example, each of the apertures can be formed with a conic shape such that the minimum aperture diameter is formed at the upper or beam entry side of the respective aperture. For example, an absorber plate can be provided with at least one metal layer at the upper or beam entry side of the absorber plate.

The charged-particle multi-beamlet generator according to the second embodiment can further comprise a source of primary charged particles and a collimating lens arranged upstream of the filter plate. According to the first example of the second embodiment, the absorber plate is arranged in the beam path of a collimated primary charged particle beam, generated by the collimating lens. For example, the absorber plate is arranged between the collimating lens and the filter plate.

According to a second example of the second embodiment, the absorber plate is arranged in a diverging primary charged particle beam between the source and the collimating lens. The charged-particle multi-beamlet generator can further comprise a collecting lens arranged between the source of primary charged particles and the absorber plate. The absorber plate has a plurality of fourth apertures arranged at a first pitch P1, configured for generating during use a plurality of preformed beamlets with the first pitch P1. The first apertures of the filter plate are arranged at a second pitch P2. The charged-particle multi-beamlet generator further comprises a control unit, which is configured to provide during use a first control signal to the first collector lens to adjust a current of the plurality of primary charged particle beamlet and configured to provide a second control signal to the collimator lens to match the pitch P1 of the plurality of preformed beamlets with the second pitch P2 of the filter plate and to adjust the propagation angles of the plurality of preformed beamlets to form a bundle of parallel preformed beamlets. In an analogous manner, the absorber plate can be arranged in a converging primary charged particle beam between the source and the collimating lens.

According to an example, the absorber plate comprises at least a layer comprising a material of a group of materials comprising Molybdenum, Ruthenium, Rhodium, Palladium or Silver, Tungsten, Rhenium, Osmium, Iridium, Platinum, or Gold. With a thickness of for example of about 50 μm to 300 μm, sufficient stopping power for scattered charged particles as well as for X-rays can be provided. In an example, the absorber plate is provided with a conductive layer formed from a material or material composition with lower atomic mass number. Thereby, the generation of secondary electrons is reduced. For example, the conductive layer is a metal layer, a graphite layer, or a doped semiconductor layer. Suitable metals with low atomic mass number at aluminum, manganese, copper or silver.

With the at least one absorber plate according to the second embodiment, the impact of scattered primary charged particles and secondary electrons in a primary multi-beamlet-forming unit can be further reduced. Furthermore, the impact of other secondary radiation such as X-ray radiation can further be reduced, and a lifetime of the primary multi-beamlet-forming unit is increased. Furthermore, a charging or a damage of an active array-optical element due to X-rays, scattered charged particles and secondary electrons is reduced.

The third embodiment of the disclosure provides a system and method configured to reduce the impact of scattered primary charged particles and secondary electrons. According to the third embodiment, a method of operating a multi-beam forming unit of a multi-beam charged particle microscope is provided. The method comprises the step of generating and providing a plurality of voltages to the elements of the multi-beam forming unit, configured for reducing the impact of secondary electrons.

The plurality of voltages comprises a first voltage U1, provided to a filter plate. The filter plate comprises a plurality of first apertures for generating of transmitting during use a plurality of primary charged particle beamlets. The plurality of voltages comprises a plurality of individual fourth voltages U4 to a plurality of electrodes, the electrodes being arranged in the vicinity of a plurality of third apertures of an active array optical element, each electrode being configured for generating an electrical field for focusing, deflecting or shaping one of the primary charged-particle beamlets. The plurality of voltages comprises a second voltage U2, provided to a shielding multi-aperture plate arranged between the filter plate and the active array optical element. The plurality of voltages including the second voltage U2 are adjusted to achieve a repelling or attracting force on secondary electrons, generated from a primary charged particle beam at intersection points with the filter plate. Generally, the plurality of voltages U0, U1, U2, U3, U4 and U5 are chosen to form a potential distribution G along the propagation direction of the primary charged particle beamlets such that at least one of the following three examples emerges. In example A, a potential barrier (in the form of a potential step A1 or a potential maximum A2) is formed along the z-axis that prevents low-energy secondary or scattered electrons from reaching the active array optical element. In example B, a potential distribution is tailored such that the beam-forming aperture or filter plate lies in a potential sink B1 formed along the z-axis. In this situation, secondary or scattered electrons originating at the energy minimum of the sink cannot escape the potential sink along the z-axis and are effectively prevented from further penetrating into the elements downstream of the filter plat. In example C, the voltages U0 and U1 are chosen such that during use, an electric field is formed between the absorber plate and the filter plate that pulls the secondary or scattered electrons into the negative z-direction, away from the active array optical element.

In a first example, a first voltage U1 provided to the filter plate is selected to generate a sink for secondary electrons. For example, U1 is selected to be larger that U2. In a second example, a second voltage U2 provided to the shielding aperture plate is selected to generate a barrier for secondary electrons. For example, U2 is smaller with respect to U1, for example U2 is selected to be negative with respect to ground level U0 with U2=U0−US. The primary charged particles have typically a large kinetic energy of about EK=5−35 keV, corresponding to a voltage difference of UE=5-35 kV. To effectively block secondary electrons, a shielding voltage US of less than 0.3% of UE is sufficient. In an example, the shielding voltage US is about 100V. With such low voltages US<0.3%×UE, secondary electrons are effectively reduced while primary charged particles are only slightly influenced. In an example, the shielding voltage US is about 10 V. Even with such a low voltage US<0.03%×UE, secondary electrons are effectively reduced while primary charged particles are only slightly influenced.

### BRIEF DESCRIPTION OF THE DRAWINGS

The disclosure will be understood even better with reference to the accompanying figures.

FIG. 1 shows a multi-beam imaging system.

FIG. 2 is an illustration of the primary multi-beamlet-forming unit.

FIG. 3 is an illustration of the generation of unwanted secondary radiation.

FIG. 4 is an illustration of the prior art.

FIG. 5 is an illustration of a first example according to the first embodiment.

FIG. 6 is an illustration of a second example according to the first embodiment.

FIGS. 7A-7D show some examples of shielding aperture plates.

FIG. 8 is an illustration of a third example according to the first embodiment.

FIG. 9 is an illustration of an example according to the second embodiment.

FIG. 10 shows a first example according to the second embodiment.

FIG. 11 shows a second example according to the second embodiment.

FIG. 12 illustrates a further example according to the second embodiment.

FIG. 13 shows an example according to the third embodiment.

FIG. 14 illustrates three examples A, B and C according to the third embodiment.

FIG. 15 illustrates the effect of an example according to the third embodiment.

FIG. 16 illustrates the effect of an example according to the third embodiment.

FIG. 17 illustrates the effect of an example according to the third embodiment.

### DETAILED DESCRIPTION

Below, the same reference signs denote the same features, even if these are not explicitly mentioned in the text.

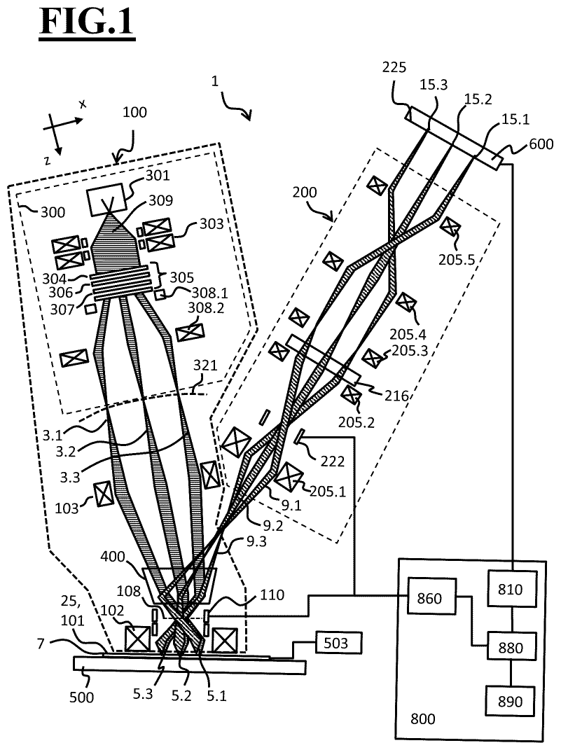

FIG. 1 is a schematic illustration of a multi-beam charged particle imaging system 1 (in short also multi-beam system 1) according to embodiments of the disclosure. The multi-beam system 1 uses a plurality of charged particle beams for forming an image of an object 7. The multi-beam system 1 generates a plurality of J primary particle beams 3 which strike the object 7 to be examined in order to generate interaction products, e.g. secondary electrons, which emanate from the object 7 and are subsequently detected. The multi-beam system 1 is of the scanning electron microscope (SEM) type, which uses a plurality of primary electron beams 3 which are incident on a surface of the object 7 at a plurality of locations and generate there a plurality of primary electron beam focus spots 5, that are spatially separated from one another. The object 7 to be examined can be of any desired type, e.g., a semiconductor wafer or a semiconductor mask, and can comprise an arrangement of miniaturized elements. The surface 25 of the object 7 is arranged in an object plane 101 of an objective lens 102 of an illumination system 100.

A diameter of the minimal beam spots or focus spots 5 shaped in the object plane 101 can be small. Exemplary values of this diameter are below 5 nanometers, for example 4 nm or 3 nm or less. The focusing of the primary charged particle beamlets 3 for shaping the focus spots 5 is carried out by the objective lens system 102. In this case, the objective lens system 102 can comprise a magnetic immersion lens. Further examples of focusing mechanisms are described in the German patent DE 102020125534 B3, the entire content of which is herewith incorporated in the disclosure.

The plurality of focus spots 5 of the primary beams form a regular raster arrangement of incidence locations, which are formed in the object plane 101. The number J of beamlets primary beamlets may be five, twenty-five, or more. In practice, the number of beamlets J, and hence the number of incidence locations or focus spots 5, can be chosen to be significantly greater, such as, for example, J=10×10, J=20×30 or J=100×100.

Exemplary values of the pitch P between the incidence locations are 1 micrometer, 10 micrometers, or more, for example 40 micrometers. For sake of simplicity, only three primary beamlets 3.1, 3.2 and 3.3 with corresponding focus points 5.1, 5.2 and 5.3 are shown in FIG. 1.

The primary particles of the primary beamlets 3 striking the object 7 generate interaction products, e.g. secondary electrons, back-scattered electrons or primary particles that have experienced a reversal of movement for other reasons, which emanate from the surface of the object 7. The interaction products are emanating from the surface of the object 7 and are shaped by the objective lens 102 to form secondary electron beamlets 9. For sake of simplicity, through the disclosure, all the interaction products are collectively described as secondary electrons, forming secondary electron beamlets 9.

The multi-beam system 1 provides a detection beam path for guiding the plurality of secondary particle beamlets 9 to a secondary electron imaging system 200. The secondary electron imaging system 200 comprises several electron-optical lenses 205.1 to 205.5 for directing the secondary particle beams 9 towards a spatially resolving particle detector 600. The detector 600 is arranged in the image plane 225. The detector 600 comprises a plurality of detection elements. Detection elements can for example be diodes such as PMDs, or CMOS detection elements, provided with electron-to-light conversion elements, or can be formed as direct electron detection elements. In an example, the detector 600 comprises an electron-to-light conversion element, such as a scintillator plate, by which secondary electrons are converted into light, and a plurality of light detection elements.

The imaging with the secondary electron imaging system 200 is strongly magnifying such that both the raster pitch of the primary beams on the wafer surface and the size and shape of focal points of the primary beams are imaged in much magnified fashion. By way of example, a magnification is between 100× and 300× such that one nm on the wafer surface is imaged enlarged to between 100 nm and 300 nm. In the process, an image field of a multi-beam system with for example 100 μm diameter is enlarged to approximately 30 mm.

The primary particle beams 3 are generated in a beam generation apparatus 300 comprising at least one particle source 301 (e.g. an electron source), at least one collimation lens 303, a primary multi-beamlet-forming unit 305 and a first field lens 308.1 and a second field lens 308.2. The particle source 301 generates at least one diverging particle beam 309, which is at least substantially collimated by the at least one collimation lens 303, and which illuminates the primary multi-beamlet-forming unit 305. The primary multi-beamlet-forming unit 305 comprises least one first multi-aperture plate or filter plate 304, which has a plurality of J openings formed therein in a first raster arrangement. Particles of the illuminating particle beam 309 pass through the J apertures or openings of the filter plate 304 and form the plurality J of primary beamlets 3. Particles of the illuminating beam 309 which strike the filter plate 304 are absorbed by the latter and do not contribute to the formation of the primary beamlets 3. A primary multi-beamlet-forming unit 305 usually has at least a further active multi-aperture plate 307, for example a lens array, a stigmator array or an array of deflection elements. Together with the field lens 308.1 and a second field lens 308.2, the primary multi-beamlet-forming unit 305 focuses each of the primary beamlets 3 in such a way that focal points are formed in an intermediate image surface 321. Alternatively, the beam foci and the intermediate image surface 321 can be virtual. The intermediate image surface 321 can be curved to pre-compensate a field curvature of the imaging system arranged downstream of the intermediate image surface 321.

The at least one field lens 103 and the objective lens 102 provide a first imaging particle optical unit for imaging the surface 321, in which the beam foci are formed, onto the object plane 101 such that the focus spots 5 of the primary beamlets are formed there. Typically, the surface 25 of the object 7 is arranged in the object plane 101, and the focal points 5 are correspondingly formed on the object surface 25. The plurality of primary beamlets 3 form a crossover point 108, in the vicinity of which a first scanning deflector 110 is arranged. The first scanning deflector 110 is used to deflect the plurality of primary beamlets 3 collectively and synchronously such that the plurality of focus spots 5 are moved simultaneously over the surface 25 of the object 7. The first scanning deflector 110 is driven by a scanning control unit 860 such that in an inspection mode of operation, a plurality of two-dimensional image data of the surface 25 are acquired. Additionally, the multi-beam system 1 can comprise further static deflectors configured to adjust the position of the plurality of the primary beamlets 3.

The objective lens 102 and the projection lenses 205 provide a secondary electron imaging system 200 for imaging the object plane 101 onto the detection plane 225. The objective lens 102 is thus a lens or a lens system that is part of both the first and the second particle optical unit, while the field lenses 103, 307 and 308 belong only to the first particle optical unit 100, and the projection lenses 205 belongs only to the secondary electron imaging system 200.

A beam divider 400 is arranged in the beam path of the first particle optical unit 100 between the field lens 103 and the objective lens system 102. The beam divider 400 is also part of the second optical unit in the beam path between the objective lens system 102 and the projection lenses 205.

The first deflection scanner 110 is arranged in a primary electron beam path or in a joint electron beam path. In the example shown in FIG. 1, the secondary electron beamlets 9 transmit during use the first deflection scanner 110 in opposite direction and the scanning movement of the secondary beamlets 9 is partially compensated. The secondary electrons have typically a different kinetic energy compared to the primary electrons. Therefore, the scanning movement of the moving irradiation positions is only partially compensated. To fully compensate the scanning movement of the secondary electron beamlets 9, the second deflection scanner 222 is arranged in the secondary electron beam path. The secondary electron imaging system 200 comprises the second, collective beam deflector 222 which is arranged in the vicinity of a crossover point of the secondary electron beamlets 9. The second, collective beam deflector 222 is operated synchronously with the first beam deflector 110 and compensates during use a beam deflection of the secondary electron beamlets 9 such that the focal points 15 of the secondary beamlets 9 remain at constant position on the detection plane 225.

The secondary electron imaging system 200 comprises electron-optical lenses 205.1 to 205.5 to adjust a focus plane of the focus spots 15 of the secondary electron beamlets 9. The electron-optical lenses 205.1 to 205.5 are shown as magneto-optical elements but are not limited to magneto-optical elements and can comprise also electro-static lens elements or stigmators. With the electron-optical lenses 205.1 to 205.5, the focus spots 15 of the secondary electron beamlets 9 can be focused into the image plane 225 of the secondary electron imaging system 200. The secondary electron imaging system 200 comprises a plurality of further components, for example at least one of a multi-aperture array element, a deflector or an exchangeable aperture stop. Together with the objective lens 102, the lenses serve to focus the secondary beams 9 on the spatially resolving detector 600 and, in the process, compensate the imaging scale and the twist of the plurality of secondary electron beamlets 9 as a result of a magnetic lens such that a third raster arrangement of the focal points 15 of the plurality of secondary electron beamlets 9 remains constant on the detector plane 225. For example, a first and second magnetic lenses 205.4 and 205.4 are designed in reversed order to one another and have oppositely directed magnetic fields. A Larmor rotation of the secondary electron beamlets 9 can be compensated by suitably driving the magnetic lenses 205.4 and 205.5. The secondary electron imaging system 200 has further correction elements available, for example a multi-aperture plate 216.

Further information relating to such multi-beam particle beam systems and components used therein, such as, for instance, particle sources, multi-aperture plate and lenses, can be obtained from the international patent applications WO 2005/024881, WO 2007/028595, WO 2007/028596, WO 2011/124352 and WO 2007/060017 and the German patent applications having the publication numbers DE 10 2013 016 113 A1 and DE 10 2013 014 976 A1, the disclosure of which in the full scope thereof is incorporated by reference in the present application.

The multi-beam charged particle imaging system 1 furthermore comprises a control system 800 configured both for controlling the individual particle optical components of the multiple particle beam system and for evaluating and analyzing the signals obtained by the detector 600. In this case, the control or controller system 800 can be constructed from a plurality of individual computers or components. By way of example, the control unit 800 comprises a control processor 880 and a control module 840 for the control of the electron-optical elements of the secondary electron imaging system 200 and the object irradiation system 100. The control unit 800 is further connected to a control module 503 for supplying a voltage to the sample 7, said voltage also being referred to as extraction voltage. Thereby, during use, an extraction field is generated between the objective 102 and the surface 25 of the object 7. During use, the extraction field decelerates the primary charged particles of the primary beamlets 3 before the sample surface 25 is reached and generates an additional focusing effect on the plurality of primary beamlets 3. At the same time, the extraction field serves during use to accelerate the secondary particles out of the surface 25 of the object 7.

Further, the control unit 800 comprises the scanning control module 860. During an inspection mode of operation, a plurality of focus points 15 of secondary electron beamlets is formed in the detection plane 225, and a plurality of signals is recorded during scanning operation of the primary beamlets 3 over the surface 25 of the sample 7. According to the disclosure, the detector 600 comprises a plurality of sets of detection elements with one set of detection elements for each secondary electron beamlet 9.

During use, each set of detection elements is configured to record the intensity signal of the assigned secondary electron beamlet 9. The plurality of intensity signals for the plurality of secondary electron beamlets 9 is transferred to the image data acquisition unit 810, where the image data is processed and stored in memory 890. The setup of the components of the multi-beam charged particle imaging system 1 is initially determined and stored in the memory 890 of the control unit 800 of the multi-beam charged particle imaging system 1.

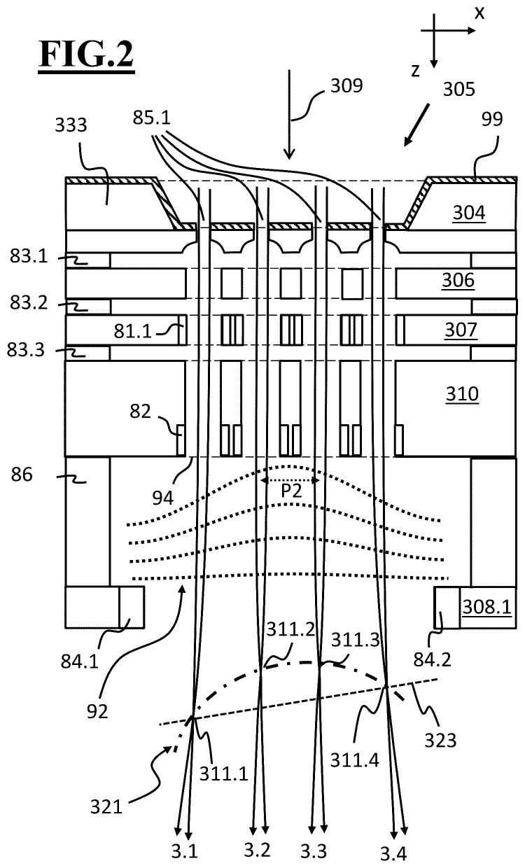

A multi-beam charged particle imaging systems 1 according to the first embodiment comprise a charged-particle multi-beamlet generator 300 with a primary multi-beamlet-forming unit 305 for generating a plurality of primary charged particle beamlets 3. A primary multi-beamlet-forming unit 305 is illustrated in FIG. 2. The primary multi-beamlet-forming unit 305 comprises, in direction of the propagating primary charged particles of the primary charged particle beam 309, a filter plate 304, a second multi-aperture plate 306, an active array-optical element 307 and a terminating multi-aperture plate 310. Each multi-aperture plate can further comprise a support zone 333 of larger thickness. The filter plate 403 is covered with a conductive coating 99, which is configured to absorb a major part of the incident charged particles from the primary charged particle beam 309. Through the plurality of first apertures 85.1, the plurality of primary charged particle beamlets 3.1 to 3.4 is formed. Each of the multi-aperture plates 304, 306, 307 and 310 comprise a plurality of apertures 85.1 to 94. In FIG. 2, labels are provided only for the apertures 85.1 of the filter plate 304 and for one aperture 94 of the terminating multi-aperture plate 310. The plurality of apertures 85.1 to 94 of each multi-aperture plate 304, 306, 307 and 310 are provided within the same raster arrangement and pitch P2 and form a parallel sequence of apertures, such that the collimated particle beamlets 3.1 to 3.4 can propagate straight through each of the sequence of apertures. The primary multi-beamlet-forming unit 305 further comprises at least a first condenser electrode 308.1 and a plurality of spacers 83.1 to 83.3 and 86. The condenser lens electrode 308.1 is configured for generating during use an electrostatic immersion lens field 92, which is partially penetrating the terminating apertures 94 of the terminating multi-aperture plate 310.

The active array-optical element 307 and a terminating multi-aperture plate 310 are provided with a plurality of electrodes 81 and 82, configured for independently influencing each primary charged particle beamlet 3.1 to 3.4 individually. Thereby, focus points of the primary charged particle beamlets 3.1 to 3.4 are formed in an intermediate image plane 321, which is typically curved and can have a tilt component 323. More details about the primary multi-beamlet-forming unit 305 are disclosed in German patent application DE 102021208700.0, filed on Aug. 10, 2021, which is incorporated herewith by reference.

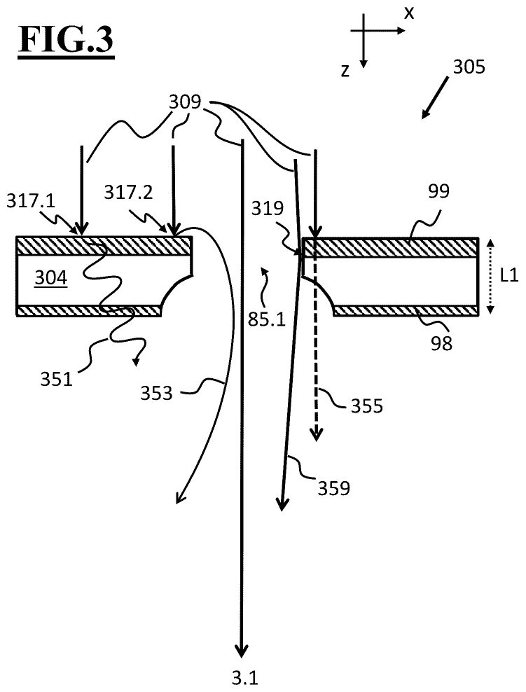

FIG. 3 illustrates the filter plate 304 and the interaction of the filter plate 304 with the primary charged particle beam 309 in more detail. The primary charged particles either transmit a first aperture 85.1, and form a primary charged particle beamlet 3.1, or impinge on the absorber coating 99 of the filter plate 304 at a plurality of intersection points 317 (only a few shown in FIG. 3). Basically, different interaction products can be generated at each of the intersection points 317. In a first example, x-ray radiation (also called Bremsstrahlung) 351 is generated. This is illustrated at intersection points 317.1. In a second example, secondary electrons are generated, which may leave the absorber coating and form secondary electron beamlet 353. In addition to secondary electrons and x-rays, some of the primary electrons may nevertheless pass the filter plate 304 and from a transmitted electron beam 355. It is also possible that a primary charged particle is scattered at for example a contamination particle at a scattering point 319 inside the aperture 85.1, and a scattered electron beamlet 359 is generated. Thus, downstream of the filter plate 304, not only the primary charged particles forming the primary charged particle beamlet 3.1 are present, but also secondary radiation 351, secondary electrons 353, scattered charged particles 359 and transmission-scattered charged particles 355 may be present. This unwanted radiation and unwanted charged particles lead to an unwanted charging, contamination and damaging of the optical elements in proximity to the filter plate 304.

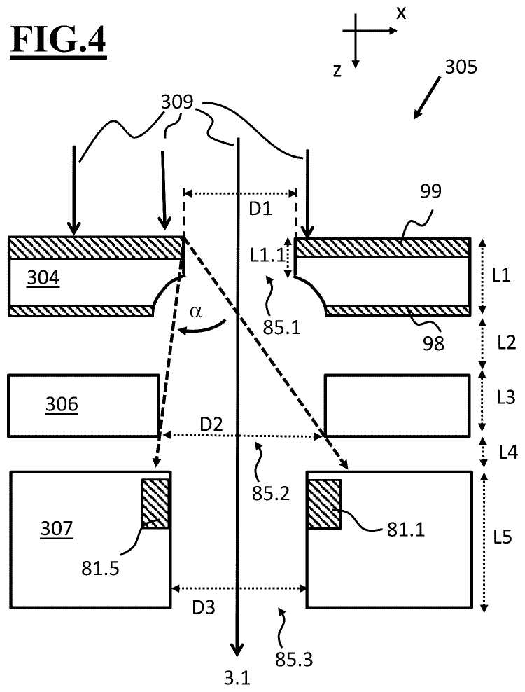

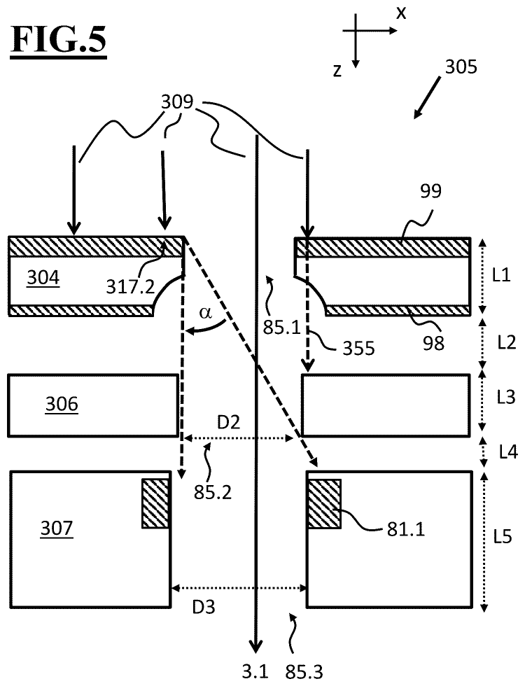

FIG. 4 illustrates the geometrical properties of a typical primary multi-beamlet-forming unit 305 according to the prior art. The filter plate 304 has an absorber layer 99, an electrode layer 98 and a plurality of apertures 85.1 with a diameter D1. The filter plate (304) has a first thickness L1. L1 can be kept at a low thickness below 20 μm, for example L1<=10 μm. The filter plate 304 may even have a reduced thickness L1.1 at each of the plurality of apertures 85.1. Thereby, the generation of scattered charged particles 359 inside the apertures 85.1 is reduced. However, the reduction of thickness increases the rate of transmitted charged particles 355. A second multi-aperture plate 306 has second apertures 85.2 with larger diameter D2>D1 and a thickness L3. The filter plate 304 and the second multi-aperture plate 306 are arranged with a gap of thickness L2 in between. The active array-optical element 307 has third apertures 85.3 and a thickness L5. The third apertures 85.3 have a diameter D3<D2. The second multi-aperture plate 306 and the active array-optical element 307 are arranged with a gap of thickness L2 in between. At each of the third apertures 85.3, at least one electrode 81.1 to 81.8 is arranged, for example there are eight electrodes 81.1 to 81.8 arranged, by which a primary charged particle beamlet 3.1 can be influenced during use (while only two electrodes 81.1 and 81.5 are visible in the cross section of FIG. 5). Each electrode (81) is connected to the control unit (800), configured to provide to each electrode (81) a voltage for individually influencing during use each primary charged particle beamlet (3). For example, the first active array optical element (307) can comprise a plurality of ring electrodes (82), configured for independently generating electrostatic fields for focusing each of the primary charged particle beamlets (3). For example, the first active array optical element (307) can comprise a plurality of multi-pole electrodes (81), configured for independently generating electrostatic fields for deflecting each of the primary charged particle beamlets (3) or for focusing or for correcting aberrations. The second multi-aperture plate 306 or the electrode layer 98 of the filter plate can be configured as counter-electrodes to form for example an Einzel lens. In designs of the prior art, the second diameters D2 of a second multi-aperture plate 306 have been selected relatively large to avoid a negative impact on a primary beamlet 3.1, wherein in relation to the second diameter D2, the third diameter D3 has been selected relatively small (D3<D2). Thereby, the voltage provided to the electrodes 81.1 to 81.8 is reduced, which is involved for generating during use the electrostatic field for influencing the primary beamlets 3. From the edge of the first apertures 85.1, an opening angle α is formed approximately with tan(α)=D2/(L1+L2+L3). The large opening angle α of the prior art has the disadvantage that unwanted radiation and unwanted charged particles may hit the active array-optical element 307 and generate a parasitic influence on the electrostatic field generated by the electrode 81.1 to 81.8, leading to a degradation of the focus spots generated by the primary multi-beamlet-forming unit 305. For example, secondary electrons 353 may stick to the upper surface of the active array-optical element 307 and generate an additional electrical field. Such parasitic charges will accumulate over time and gradually reduce the performance of a primary multi-beamlet-forming unit 305.

FIG. 5 illustrates a first embodiment of the disclosure. According to a first example, distance L2, the thicknesses L1 and L3 and the second diameter D2 are selected such that a reduced opening angle is formed with tan(α)<0.3, such as tan(α)<0.25. The reduction of the opening angle is achieved by a selection of the aperture diameters D2 in relation to D3, such that D2<D3. In an example D2 is selected in a range between 1.1×D1 and 1.3×D1. The third apertures (85.3) have a third diameter D3, and D2 is selected to be smaller than D3. For example, D3>1.6×D1, but D3 can even be selected with D3>=1.8×D1. Thereby, the active array-optical element (307) is physically shielded by the second multi-aperture plate (306), and the number of secondary electrons or scattered primary charged particles impinging on the active array-optical element (307) is reduced. Therefore, according to the disclosure, the second multi-aperture plate (306) is also referred to as a shielding multi-aperture plate (306). For example, D2 is selected in the interval 0.625×D3<=D2<=1.3×D1. For example, D2=1.3×D1 and D3=1.8×D1. For example, D2=1.2×D1 and D3=1.7×D1. For example, D2=1.1×D1 and D3=1.6×D1. For example, by achieving approximately a ratio of D2/D3<=0.75, the electrodes (81, 82) of active array-optical element (307) are shielded by the shielding multi-aperture plate (306), and the number of secondary electrons or scattered primary charged particles impinging on the electrodes (81, 82) is effectively reduced. The opening angle α is for example reduced by a reduced diameter D2 of for example D2<1.3×D1, for example with D2<=40 μm. With a reduced diameter D2 of the shielding multi-aperture plate (306), a reduction of the opening angle α is achieved and more transmitted charged particles 355 are absorbed by the shielding multi-aperture plate (306).

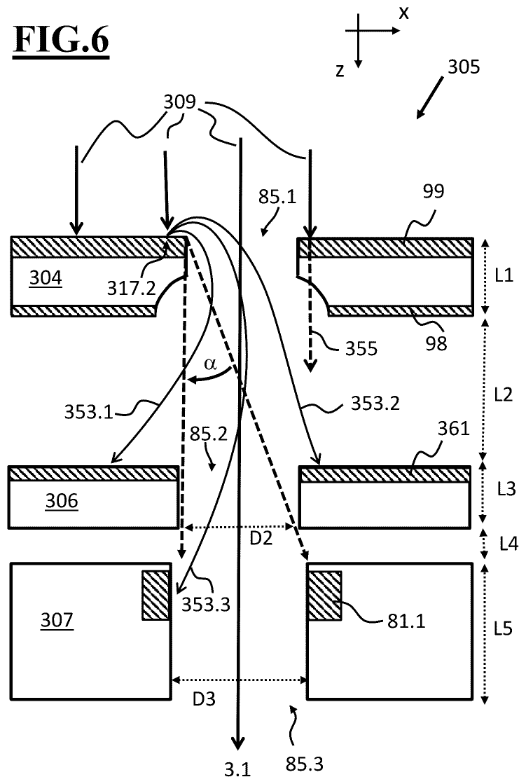

The opening angle α is for example further reduced by an increased distance L2 of for example L2>70 μm, for example L2=100 μm. An example of increased distance L2 is illustrated in FIG. 6. Thereby, the probability that scattered or transmitted charged particles 359, 355 and secondary electrons 353.1, 355.2 are absorbed at the shielding multi-aperture plate (306), where they may not cause any harm, is even increased. The opening angle α is for example further reduced by an increased thickness L3 of for example L3>70 μm, for example L3=120 μm.

In an example, at least one of a thickness or distance L2 or L3 is increased and the diameter D2 is reduced. In an example, the sum of the thicknesses and distance (L1+L2+L3) is selected to exceed 130 μm, for example (L1+L2+L3)=150 μm. For example, to reduce the generation of scattered charged particles 359, the thickness of the filter plate 304 is selected to be L1=10 μm, the distance is selected with L2=20 μm and L3=120 μm. For example, the thickness of the filter plate 304 is selected to be L1=10 μm, the distance is selected with L2=70 μm and L3=70 μm.

The shielding multi-aperture plate (306) may further be provided with at least an absorbing or metal layer (361), covering the beam entry side of the shielding multi-aperture plate (306). According to an example, the absorbing or metal layer (361) comprises a material of a group of materials comprising Molybdenum, Ruthenium, Rhodium, Palladium or Silver, Tungsten, Rhenium, Osmium, Iridium, Platinum, or Gold. Such a layer with a thickness of for example of about 1-2 μm can provide sufficient stopping power for scattered charged particles 359 and secondary electrons 353. In a further example, the shielding multi-aperture plate (306) may further be provided with at least an absorbing or metal layer (361), covering the beam exit side of the shielding multi-aperture plate (306). In a further example, the shielding multi-aperture plate (306) is made of an absorbing material, for example a material of the group comprising Molybdenum, Ruthenium, Rhodium, Palladium or Silver, Tungsten, Rhenium, Osmium, Iridium, Platinum, or Gold, or alloys thereof.

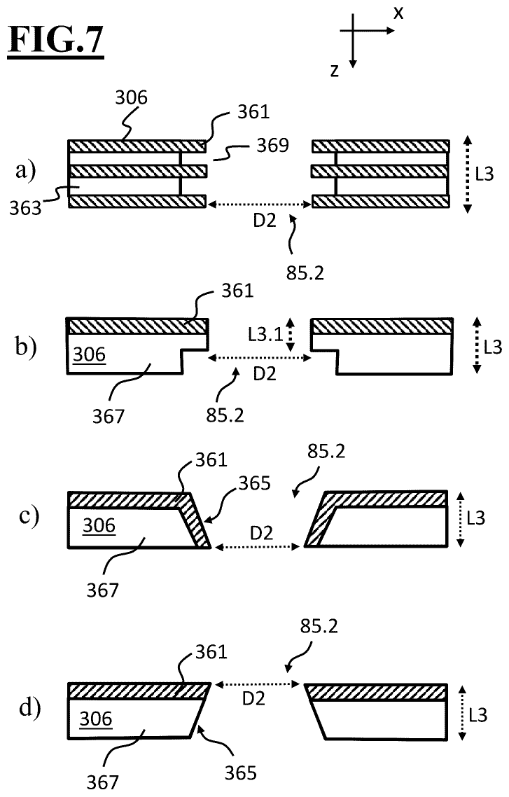

According to a further example of the first embodiment, the shielding multi-aperture plate (306) can further be configured for a reduction of scattered charged particles 359 and secondary electrons 353. Some mechanisms for the reduction of scattered charged particles 359 and secondary electrons 353 are illustrated in FIGS. 7A-7D. In a first example shown in FIG. 7A, at each of the second apertures (85.2) of the shielding multi-aperture plate (306), at least one baffle (369) for absorbing scattered charged particles and secondary electrons is formed. A plurality of baffles 369 can for example be formed by stacking of a plurality of metal layers 361 and isolating layers 363 on top of each other. The conducting metal layers 361 can be connected to ground level. In a second example shown in FIG. 7B, the shielding multi-aperture plate (306) is formed with a two-layer structure and each of the apertures (85.2) with diameter D2 is formed within a first layer with a thickness L3.1<L3. Thereby, scattering of charged particles or electrons inside the second apertures (85.2) is reduced. In the second example, with a second aperture 85.2 of reduced thickness, the diameter D2 of the second aperture can be reduced even further, for example D1<D2<1.15×D1. In a third example shown in FIG. 7C, each of the second apertures (85.2) of the shielding multi-aperture plate (306) is formed with a conic shape (365) such that the minimum aperture diameter D2 is formed at the bottom or beam exit side of the shielding multi-aperture plate (306). The absorbing layer (361) may also cover the conic shaped aperture openings (85.2). Thereby, by having the minimum diameter D2 at the bottom or beam exit side of the shielding multi-aperture plate (306), the opening angle α is further reduced to a minimum. Thereby, the protection or shielding of the active array-optical element (307) by the shielding multi-aperture plate (306) can be improved.

In a fourth example (shown in FIG. 7D), each of the second apertures of the shielding multi-aperture plate is formed with a conic shape such that the minimum aperture diameter D2 is formed at the top or beam entry side of the shielding multi-aperture plate (306). Thereby, and similar to the second example shown in FIG. 7B, the cross-section area of the aperture with the scattered charged particles (359) or secondary electrons (353) is reduced and surface contamination induced by scattered charged particles (359) or secondary electrons (353) is reduced. In the examples according FIG. 7B or 7D, the opening angle α is formed approximately with tan(α)=D2/(L1+L2) or tan(α)=D2/(L1+L2+L3.1). To keep the opening angle small, a larger distance L2 or a smaller diameter D2 might be used is these examples.

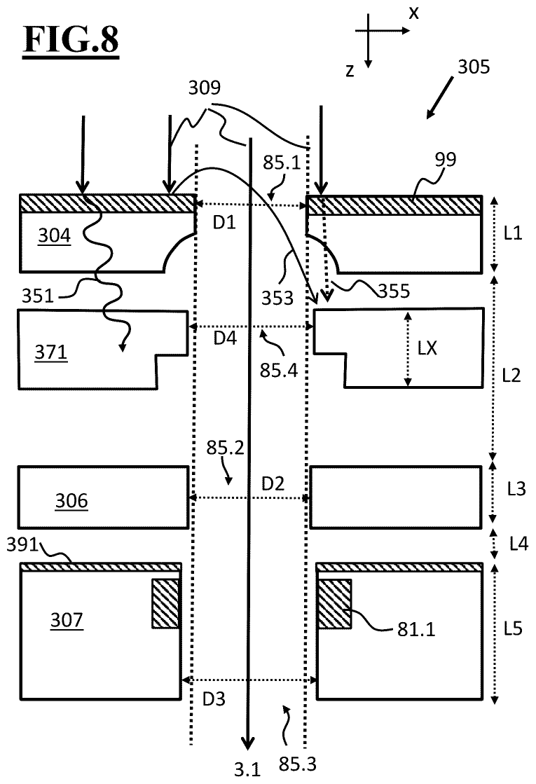

FIG. 8 shows another example according to the first embodiment. In an example, the primary multi-beamlet-forming unit (305) further comprises a further multi-aperture plate, formed as an absorber plate (371) between the filter plate (304) and the shielding multi-aperture plate (306). The diameter D4 of fourth apertures (85.4) of the absorber plate (371, 371.1) is selected to be between the first diameter D1 and the third diameter D3, for example D4 is selected in a range 1.1×D1<D4<=D3. The thickness of the absorber plate (371) is LX. Details of the absorber plate (370) are described below at the second embodiment in more detail.

The primary multi-beamlet-forming unit (305) may comprise further multi-aperture plates, including further active array-optical multi-aperture plates and a terminating multi-aperture plate (310).

According to the first embodiment of the disclosure, an acceptance or opening angle α for transmitted, scattered charged particles 355, 359 or secondary electrons 353 is reduced, and a charging or damaging or contamination of the first active array-optical element (307) is reduced and a lifetime of a primary multi-beamlet-forming unit 305 is increased. With opening angle α the

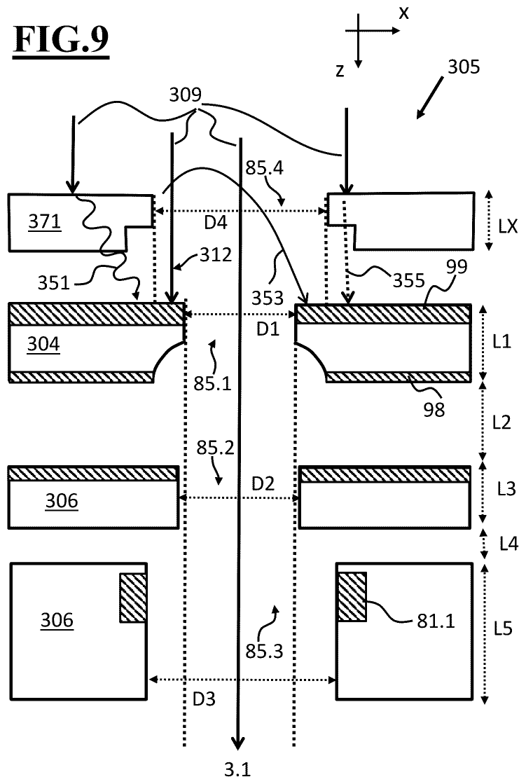

The impact of scattered charged particles and secondary electrons can be further reduced according to the second embodiment of the disclosure. An example according to the second embodiment of the disclosure is illustrated in FIG. 9. FIG. 9 shows a multi-beam forming unit (305) with a filter plate (304) and a first active array optical element (307). The filter plate (304) comprises a plurality of first apertures (85.1), each with a first diameter D1 for generating during use the plurality of primary charged particle beamlets (3). The first active array-optical element (307) comprises a plurality of third apertures (85.3), each with a third diameter D3, similar to the first active array-optical element (307) described in the first embodiment of the disclosure. The charged-particle multi-beamlet generator (300) further comprises a first absorber multi-aperture plate (371) with a plurality of fourth apertures (85.4) with a diameter D4. In the example of FIG. 9, the first absorber multi-aperture plate (371) (short: absorber plate 371) is arranged upstream of the filter plate (304). The diameter D4 of the fourth apertures (85.4) is selected to be larger than the diameter D1 of the first apertures (85.1). During use, a primary charged particle beam (309) is first impinging on the first absorber plate (371). Most primary charged particles are absorbed by the first absorber plate (371), and the primary charged particles passing the fourth apertures (85.4) are forming pre-shaped charged particle beamlets (312). The pre-shaped charged particle beamlets (312) are impinging on the filter plate (304). A part of the pre-shaped charged particle beamlets (312) is absorbed by the filter plate (304), and the primary charged particles passing the first apertures (85.1) are forming the primary charged particle beamlets (3).

In an example, the diameter D4 of fourth apertures (85.4) of the absorber plate (371) is selected to be between the first diameter D1 and the third diameter D3, for example D4 is selected in a range 1.1×D1<D4<=D3. With the absorber plate (371), the number of charged particle impinging on the filter plate 304 is reduced and transmitted charged particles 355 and secondary electrons 353 are generated at the absorber plate 371 instead. Therefore, the number of transmitted charged particles 355 and secondary electrons 353 downstream of the filter plate (304) is effectively reduced.

In the example according to FIG. 9, the primary multi-beamlet-forming unit (305) further comprises a shielding multi-aperture plate (306) with second apertures (85.2) with a second diameter D2, the shielding multi-aperture plate (306) having a third thickness L3; wherein 1.1×D1<D2<=1.5×D1. In an example, the shielding multi-aperture plate (306) within the primary multi-beamlet-forming unit (305) is configured for a reduction of the opening angle α and arranged according to the first embodiment of the disclosure.

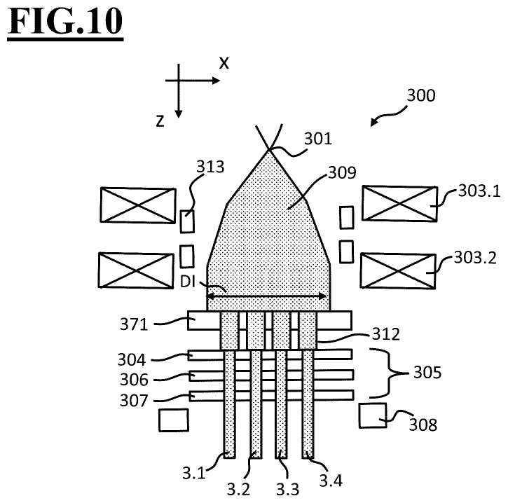

A first example of a charged-particle multi-beamlet generator (300) according to the second embodiment is illustrated in FIG. 10. The charged-particle multi-beamlet generator (300) comprises a source (301) of primary charged particles and a collimating lens (303.1, 303.2) arranged upstream of the filter plate (304). The collimating lens (303.1, 303.2) can be formed as a pair of magnetic lenses 303.1 and 303.2 and can comprise further electrostatic elements like deflector elements 313. The absorber plate (371) is arranged in the parallel beam path of a collimated primary charged particle beam (309) downstream of the collimating lens (303.1, 303.2). For example, the absorber plate (371) is arranged between the collimating lens (303.1, 303.2) and the filter plate (304). The collimated primary charged particle beam (309) has a diameter D1 at the incidence side of the absorber plate (371). The absorber plate (371) generates during use the plurality of preformed beamlets (312) as parallel beamlets, which are impinging perpendicular on the filter plate 304. Both absorber plate 371 and filter plate 304 have a plurality of apertures at the same pitch P2.

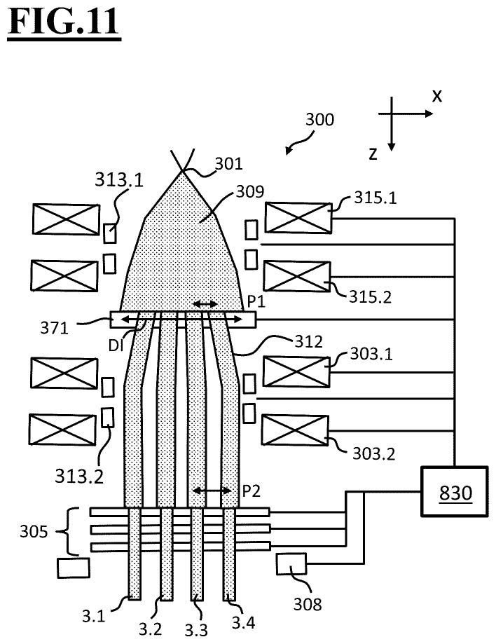

A second example of the second embodiment is illustrated in FIG. 11. The absorber plate (371) is arranged in a diverging primary charged particle beam (309) between the source (301) and the collimating lens (303.1, 303.2). The charged-particle multi-beamlet generator (300) of this example further comprises a collecting lens or lens pair (315.1, 315.2) arranged between the source of primary charged particles (301) and the absorber plate (371). The absorber plate (371) has a plurality of fourth apertures (85.4) arranged at a first pitch P1, configured for generating during use a plurality of preformed beamlets (312) with the first pitch P1. The first apertures (85.1) of the filter plate (304) are arranged at a second pitch P2. The charged-particle multi-beamlet generator (300) further comprises a control unit (830), which is configured to provide during use a first control signal to the first collector lens (315.1, 315.2) to adjust a current of the plurality of primary charged particle beamlet (3). Thereby, a collection angle of primary charged particles collected from the source 301 is adjusted by a variable focal length of the first collector lens (315.1, 315.2). The collector lens pair (315.1, 315.2) can further comprise first multipole elements 313.1 for adjusting the mean propagation direction and position of the primary charged particle beam 309 at the incidence side of the absorber plate 371. The control unit (830) is configured to provide a second control signal to the collimator lens (303.1, 303.2) to match the pitch P1 of the plurality of preformed beamlets (312) with the second pitch P2 of the filter plate (304) and to adjust the propagation angles of the plurality of preformed beamlets (312) to form a bundle of parallel preformed beamlets (312). Thereby, the bundle of parallel preformed beamlets (312) is adjusted in parallel and perpendicular to the filter plate and the primary charged particle beamlets 3 can pass the plurality of apertures within the primary multi-beamlet-forming unit (305).

The control unit (830) can be part of the charged-particle multi-beamlet generator (300) and connected to the control unit 800 of the multi-beamlet charged-particle microscopy system or can be part of the control unit 800 of the multi-beamlet charged-particle microscopy system.

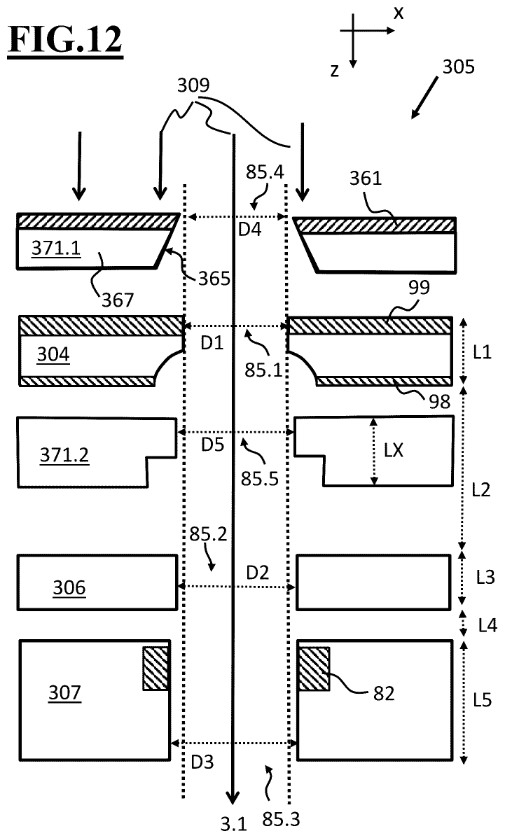

In an example illustrated in FIG. 12, the primary multi-beamlet-forming unit (305) comprises a first absorber plate (371.1) according to the examples above, and a second absorber plate (371.2) between the filter plate (304) and the shielding multi-aperture plate (306). In an example, the diameter D5 of fifth apertures (85.5) of the absorber plate (371, 371.1) is selected to be between the first diameter D1 and the third diameter D3, for example D5 is selected in a range 1.1×D1<D5<=D3. The primary multi-beamlet-forming unit (305) may comprise further multi-aperture plates, including further active array-optical multi-aperture plates and a terminating multi-aperture plate (310).

Within each of the shielding multi-aperture plate (306), the first or second absorber plate (371, 371.1, 371.2), each of the of the apertures (85.2, 85.4, 85.5) can be provided with at least on baffle (369). Each of the apertures can be formed with a conic shape (365) such that the minimum aperture diameter is formed at the beam entry of beam exit side of the respective aperture (85.2, 85.4, 85.5). At least one of the absorber plates (371, 371.1, 371.2), the shielding plate (306) and the filter plate (304) can be provided with at least one conductive layer (361, 99) at the beam entry or beam exit side of the plate (371, 371.1, 371.2, 304, 306).

According to an example, the absorber multi-aperture plate (371) comprises a material of a group of materials comprising Molybdenum, Ruthenium, Rhodium, Palladium or Silver, Tungsten, Rhenium, Osmium, Iridium, Platinum, or Gold. In an example, the thickness LX can be LX>20 μm, for example LX=30 μm or more. With a larger thickness LX compared to the thickness of the filter plate L1, a stopping power to prevent transmitted charged particles 355 is increased and an extinction of x-rays generated at the intersection with primary charged particles is increased. With a thickness of for example of about 50 μm to 300 μm, an almost complete stopping power of more than 95% of X-rays 351 can be provided. With a 60 μm layer of gold, for example, more than 95% of x-rays are absorbed. An even more reduced transmission of x-rays is for example achieved with an absorber plate (371) made of tungsten. The absorber plate (371) can further be provided with an absorbing layer (361) for absorbing electrons or other charged particles. The absorber layer (99, 361) can for example formed as a doped silicon or silicon oxide or graphite layer. Thereby, backscattering of charged particles are reduced.

With the at least one absorber plate (371, 371.1, 371.2) according to the second embodiment, the impact of scattered primary charged particles and secondary electrons in a primary multi-beamlet-forming unit (305) is further reduced. Furthermore, the impact of other secondary radiation such as X-ray radiation can further be reduced, and a lifetime of the primary multi-beamlet-forming unit (305) is increased. Furthermore, a charging or a damage of an active array-optical element (307) due to X-rays, scattered charged particles and secondary electrons is reduced.

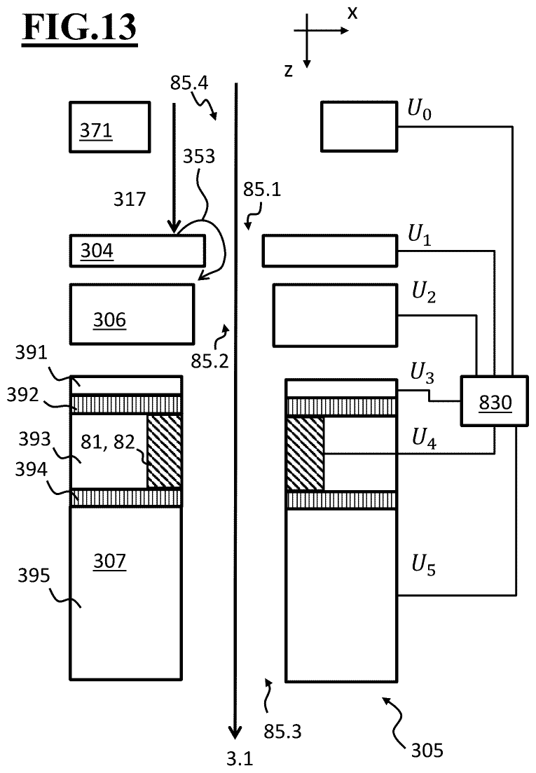

The third embodiment of the disclosure provides a further system and method configured to reduce especially the impact of secondary electrons. Secondary electrons 353, which are generated at the filter plate 304 or an absorber plate 371 typically have a much lower kinetic energy compared to the primary charged particles. According to the third embodiment, a method of operating a multi-beam forming unit (305) of a multi-beam charged particle microscope (1) and a multi-beam charged particle microscope (1) is provided, in which further mechanisms are provided to reduce a charging or damage of an active array-optical element 307 of a primary multi-beamlet-forming unit (305). A primary multi-beamlet-forming unit (305) according to the third embodiment is illustrated in FIG. 13. The primary multi-beamlet-forming unit (305) comprises a filter plate 304, a second or shielding multi-aperture plate 306 and an active array optical element (307). The active array optical element (307) comprises a first or conductive layer 391, an isolation layer 392, and electrode layer 393 comprising the plurality of electrodes (81, 82), a second isolating layer 394 and a base layer 395.

The filter plate (304) comprises a plurality of first apertures (85.1) for generating of transmitting during use a plurality of primary charged particle beamlets (3). The filter plate may comprise a conductive absorber coating 99. The active array optical element (307) comprises a plurality of electrodes (81, 82) being arranged in the vicinity of a plurality of third apertures (85.3) of the active array optical element (307), each electrode (81, 82) being configured for generating an electrical field for individually focusing, deflecting or shaping one of the primary charged-particle beamlets (3). The second multi-aperture plate 306 can be a shielding multi-aperture plate 306, arranged and configured for a reduction of an opening angle α according to the first embodiment. The primary multi-beamlet-forming unit (305) according to the third embodiment can further comprise an absorber plate 371 of the second embodiment of the disclosure. All elements are isolated with respect to each other and are electrically connected to a control unit 830. The control unit (830) is configured to provide a plurality of voltages to the elements of the multi-beam forming unit (305) for reducing the impact of secondary electrons according to the third embodiment.

The method comprises the step of generating and providing a plurality of voltages U4 to the electrodes (81, 82) of the active array-optical element (307) by the control unit 830. The voltages U4 are determined, generated and provided by control unit 830 for example based on a setup of the charged-particle multi-beamlet generator (305) which was determined during a calibration of the multi-beamlet charged-particle microscopy system (1) and stored in a memory of the control unit 800. The method further comprises the step of generating and providing a plurality of voltages to the elements of the multi-beam forming unit (305) by the control unit 830. The plurality of voltages comprises a first voltage U1, provided to a filter plate (304). The plurality of voltages comprises a plurality of individual fourth voltages U4, provided to the plurality of electrodes (81, 82). The plurality of voltages comprises a second voltage U2, provided to a second or shielding multi-aperture plate (306) arranged between the filter plate (304) and the active array optical element (307). For example, the second voltage U2 is adjusted to achieve a repelling or attracting force on secondary electrons (353), generated from a primary charged particle beam (309) at intersection points (317) with the filter plate (304). The magnitude of the first voltage U1 or the second voltage U2 is adjusted to the range of the kinetic energy of the secondary electrons 353, generated for example at the filter plate 304. Therefore, the magnitude of the first voltage U1 or the second voltage U2 is much smaller than the kinetic energy of the primary charged particles, corresponding to the voltage difference between the anode of the source 301 and the filter plate 304. The voltages U1 or U2 are selected and configured to form an potential energy sink, the depth of which is adjusted to the range of the kinetic energy of the secondary electrons 353. The primary charged particles have typically a large kinetic energy of about EK=5−35 keV, corresponding to a voltage difference of UE=5-35 kV. Secondary electrons typically have a kinetic energy of less than 100 eV, for example less than 50 eV.

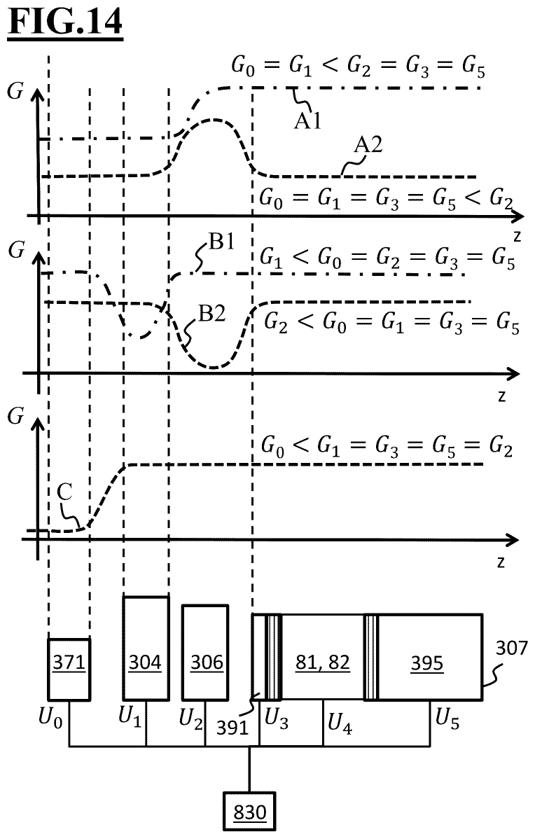

Generally, the plurality of voltages U0, U1, U2, U3, U4 and U5 are chosen such that at least one of the following three examples emerges. The three examples A, B, and C are illustrated in FIG. 14. In each example, potential energies G corresponding to the voltages U0, U1, U2, U3, U4 and U5 are illustrated. The voltages U0, U1, U2, U3, U4 and U5 used for the generation of the potentials G0, G1, G2, G3, G4 and G5 are proportional to the negative value of the potential by U˜−G.

At the bottom of FIG. 14, the multi-aperture-plates of a multi-beam forming unit are illustrated schematically, and it is referred to FIG. 13 and the description thereof. The potentials G0, G1, G2, G3, G4 and G5 along the z-axis through an aperture are corresponding to the sequence of multi-aperture plates with corresponding voltages U0, U1, U2, U3, U4 and U5 provided by control unit 830.

In example A, a potential barrier (in the form of a potential step A1 or a potential maximum A2) is formed along the z-axis that prevents low-energy secondary or scattered electrons from reaching the active array optical element (307).

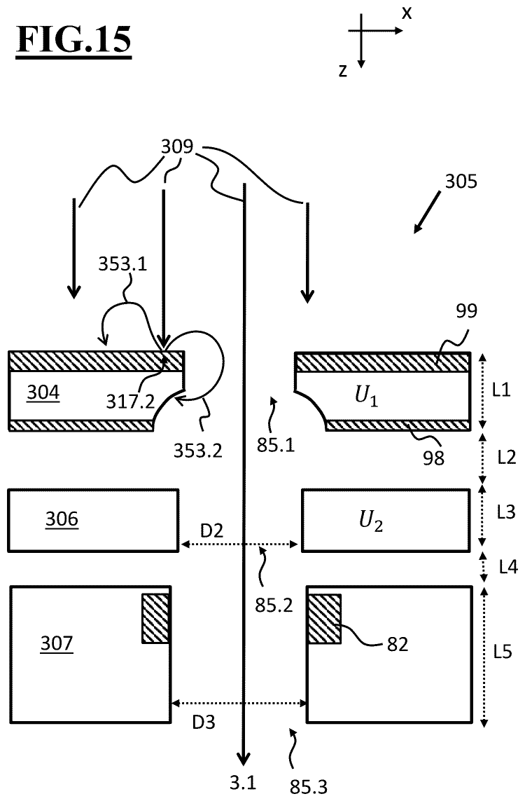

In example B, the potential landscape is tailored such that the beam-forming aperture or filter plate 304 lies in a potential sink B1 formed along the z-axis. In this situation, secondary or scattered electrons originating at the energy minimum of the sink cannot escape the potential sink along the z-axis and are effectively prevented from further penetrating into the elements downstream of the filter plate 304, including the active array optical element (307). An example is illustrated in FIG. 15. A first, positive voltage U1 provided to the filter plate (304) is selected to generate a potential sink B1 for secondary electrons. For example, U1 is selected to exceed the voltage U2 provided to the second multi-aperture plate 306 with U1=U2+US, with US below 100V.

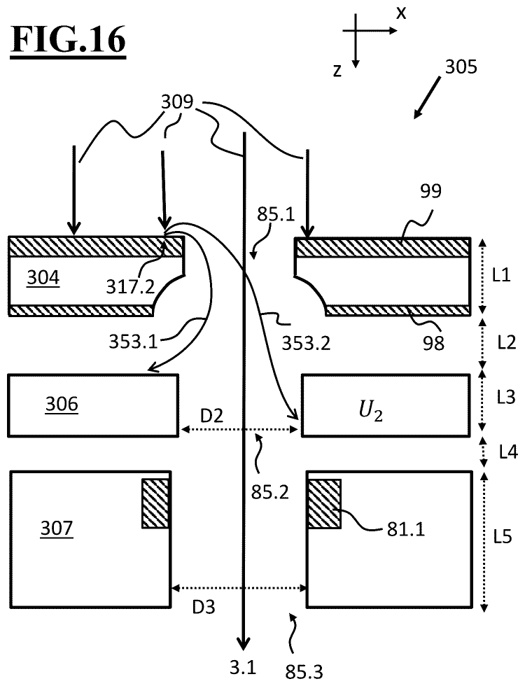

In a second example illustrated in FIG. 16, a second voltage U2 provided to the second or shielding multi-aperture plate (306) is selected to generate a sink B2 for secondary electrons (see potential G in FIG. 14). For example, U2 is selected to exceed that third voltage U3 provided to a conducting first layer 391 of the active array-optical element with U2=U3+US, with US below 100V. In an example, both U1 and U2 are exceeding U3. To effectively block secondary electrons 353, a shielding voltage US of less than 0.3% of UE is sufficient in both examples. In an example, the shielding voltage US is about 100V. With such low voltages US<0.3%×UE, secondary electrons are effectively reduced while primary charged particles are only slightly influenced. The voltages U0, U3 and U5 can be set to ground level. In an example, U1 and U2 are set to ground level and U3 is set to a negative voltage between −100V and 0 V. Ground level can be any reference level of the charged particle microscope.

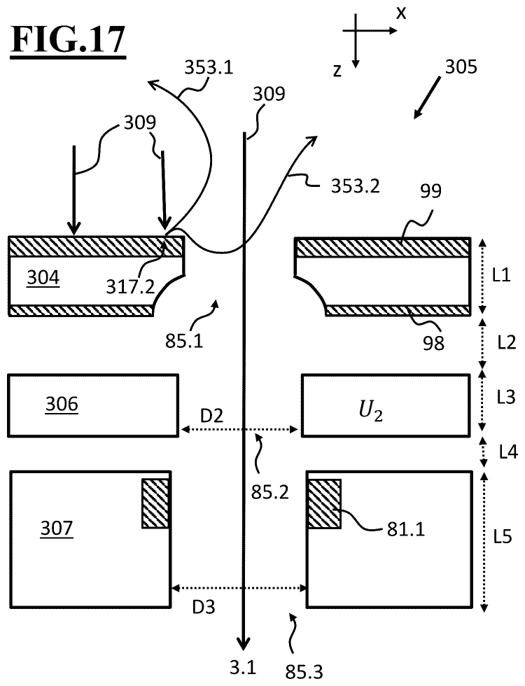

In example C, the voltages U0 and U1 are chosen such that during use, an electric field is formed between the absorber plate 371 and the filter plate 304 that pulls the secondary or scattered electrons into the negative z-direction, away from the active array optical element (307) (FIG. 17).

It is understood that also combinations of A, B and C are possible. It is understood that in some examples the absorber plate 371 or the second multi-aperture plate 306 may be omitted.

Given the small distances L2 and L4 between the multi-aperture plates, the volume of interaction of the field generated by the voltage differences between the filter plate 304, the second aperture plate 306 and the first layer 391 of the active array-optical element (307) is very small and thus does not have a significant impact on the primary charged particles at high kinetic energy, while the slow secondary electrons are effectively prevented from reaching the active array-optical element (307). Thereby, one source of charging and damaging of the active array-optical element (307) is effectively eliminated.

In the examples of the disclosure and the claims, array of electrostatic elements such as electrostatic micro-lenses or electrostatic multi-pole elements are described, to which driving voltages are provided by at least one voltage supply unit. However, active multi-aperture elements can also be configured as magneto-dynamic elements with coils instead of electrodes. In these equivalent examples, driving currents are provided instead of voltages U4 by at least one current supply unit, which can for example be comprising an ASIC or other equivalent micro-electronic devices. Therefore, coils, driving currents or current supply units are equivalent mechanisms for electrodes, driving voltages or voltage supply units and the field can be applied to magneto-dynamic array elements without difficulty.

The disclosure is further described by following clauses:

Clause 1: A method of operating a multi-beam forming unit (305) of a multi-beam charged particle microscope (1), comprising the steps of
generating a primary charged particle beam (309),
providing a first voltage U1 to a filter plate (304), the filter plate (304) comprising a plurality of apertures (85) for forming and transmitting during use a plurality of primary charged particle beamlets (3) from the primary charged particle beam (309), wherein the primary charged particle beam (309) is generating secondary electrons (353) at intersection points (317) of primary electrons of the primary charged particle beam (309) with the filter plate (304); or
providing a plurality of individual fourth voltages U4 to a plurality of electrodes (81, 82) of an active array-optical element (307), the electrodes being arranged in the vicinity of a plurality of apertures (85) of active array-optical element (307), each being configured for focusing, deflecting or shaping one of the primary charged particle beamlets (3);
providing at least one of a second voltage U2 to a second multi-aperture plate (306) arranged between the filter plate (304) and the active array-optical element (307) or an absorber plate voltage U0 to an absorber plate (371) arranged in propagation direction of the primary charged particle beam (309) upstream of the filter plate (304);
adjusting at least one of the absorber plate voltage U0, the first voltage U1 or the second voltage U2 for preventing secondary electrons (353) from intersecting with the active array-optical element (307) by either achieving a potential barrier (A1, A2) or a potential sink (B1, B2, C) for the secondary electrons (353).

Clause 1: The method according to clause 1, wherein the second voltage U2 is adjusted to be smaller than the first voltage U1, thereby either achieving a potential barrier (A1, A2) or a potential sink (B1) for the secondary electrons (353) upstream of the second multi-aperture plate (306).

Clause 3: The method according to clause 1, wherein the second voltage U2 is adjusted to be larger than the first voltage U1, thereby achieving a potential sink (B2) for the secondary electrons (353) in proximity of the second multi-aperture plate (306).

Clause 4: The method according to any of the clauses 1 to 3, wherein the absorber plate voltage U0 is adjusted to be larger than the first voltage U1, thereby achieving a potential sink (C) for the secondary electrons (353) upstream of the filter plate (304).

Clause 5: The method according to any of the clauses 1 to 4, wherein at least one of the absorber plate voltage U0, the first voltage U1 or the second voltage U2 are provided at a ground or reference level.

Clause 6: The method according to any of the clauses 1 to 5, further comprising the step of providing a third voltage U3 to a first layer (391) of the active array-optical element (307), the third voltage U3 being equal to either the first voltage U1 or second voltage U2.

Clause 7: The method according to any of the clauses 1 to 6, further comprising the step of providing a fifth voltage U5 to a fifth layer (395) of the active array-optical element (307), the fifth voltage U5 being equal to either the first voltage U1 or second voltage U2.

Clause 8: A multi-beam charged particle microscope (1), comprising
a charged particle source (301) and at least one condenser lens (303.1, 303.2) for generating a primary charged particle beam (309);
a multi-beam forming unit (305), comprising
a filter plate (304) with a plurality of apertures (85) for forming during use a plurality of primary charged particle beamlets (3) from the primary charged particle beam (309);
active array-optical element (307) with a plurality of electrodes (81, 82), the electrodes being arranged in the vicinity of a plurality of apertures (85) of active array-optical element (307), each being configured for focusing, deflecting or shaping one of the primary charged particle beamlets (3);
at least one of a second multi-aperture plate (306) arranged between the filter plate (304) and the active array-optical element (307) or an absorber plate (371) arranged in propagation direction of the primary charged particle beam (309) upstream of the filter plate (304);
a control unit (830), configured to execute during use any of the methods according to clauses 1 to 7.

Clause 9: A multi-beam charged particle microscope (1), comprising
a charged particle source (301) and at least one condenser lens (303.1, 303.2) for generating and forming a primary charged particle beam (309);
a multi-beam forming unit (305), comprising
a filter plate (304) with a plurality of apertures (85.1) with a diameter D1 for forming during use a plurality of primary charged particle beamlets (3);
an active array-optical element (307) with a plurality of apertures (85.3) with a third diameter D3, the active array-optical element (307) being configured for individually focusing, deflecting or shaping during use at least one of the primary charged particle beamlets (3);
at least one of a second multi-aperture plate (306) with apertures (85.2) with a second diameter D2, the second multi-aperture plate (306) being arranged between the filter plate (304) and the active array-optical element (307) or an absorber plate (371) with a plurality of apertures (85.4) with a diameter D4, the absorber plate (371) being arranged in propagation direction of the primary charged particle beam (309) upstream of the filter plate (304);
a control unit (830), configured to adjust and provide during use at least one of a first voltage U1 to the filter plate (304), a second voltage U2 to a second multi-aperture plate (306) or an absorber plate voltage U0 to an absorber plate (371) for preventing secondary electrons (353) generated during use at the filter plate (304) from intersecting with the active array-optical element (307) by either achieving a potential barrier (A1, A2) or a potential sink (B1, B2, C) for the secondary electrons (353) upstream of the active array-optical element (307).

Clause 10: The multi-beam charged particle microscope (1) according to clause 9, wherein
the filter plate (304) has a first thickness L1<20 μm, such as L1<=10 μm,
the second multi-aperture plate (306) is arranged at a distance L2 from the filter plate (304), and wherein the distance L2 and the thickness L1 and the second diameter D2 are selected according to D2/(L1+L2)<=0.3, such as <0.25, whereby a shielding of secondary electrons (353) or scattered primary electrons (355, 359) generated during use at the filter plate (304) can be improved.

Clause 11: The multi-beam charged particle microscope (1) according to clause 9 or 10, wherein
the filter plate (304) has a first thickness L1<20 μm, such as L1<=10 μm,
the second multi-aperture plate (306) is arranged at a distance L2 from the filter plate (304) and has a third thickness L3, and wherein the distance L2 and the thicknesses L1 and L3 and the second diameter D2 are selected according to D2/(L1+L2+L3)<=0.3, such as <0.25.

Clause 12: The multi-beam charged particle microscope (1) according to any of the clauses 9 to 11, wherein D2 and D3 are selected according D3>=D2>D1.

Clause 13: The multi-beam charged particle microscope (1) according to clause 12, wherein D2 is selected according to 1.1×D1<D2<1.3×D1.

Clause 14: The multi-beam charged particle microscope (1) according to any of the clauses 10 to 13,
wherein (L1+L2+L3)>130 μm, such as >150 μm.

Clause 15: The multi-beam charged particle microscope (1) according to any of the clauses 9 to 14, wherein within each of the apertures (85.2) of the second multi-aperture plate (306), at least one baffle (369) is formed.

Clause 16: The multi-beam charged particle microscope (1) according to any of the clauses 9 to 14, wherein within each of the apertures (85.2) of the second multi-aperture plate (306), an aperture (85.2) of diameter D2 is formed with a thickness L3.1<L3.

Clause 17: The multi-beam charged particle microscope (1) according to any of the clauses 9 to 14, wherein within each of the apertures (85.2) of the second multi-aperture plate (306) is formed with a conic shape (365).

Clause 18: The multi-beam charged particle microscope (1) according to clause 17, wherein the minimum aperture diameter D2 is formed at the bottom or beam exit side of the second multi-aperture plate (306).

Clause 19: The multi-beam charged particle microscope (1) according to clause 17, wherein the minimum aperture diameter D2 is formed at the upper or beam entry side of the second multi-aperture plate (306).

Clause 20: The multi-beam charged particle microscope (1) according to any of the clauses 9 to 19, wherein the second multi-aperture plate (306) is provided with at least one metal layer (361) at the upper or beam entry side.

Clause 21: The multi-beam charged particle microscope (1) according to any of the clauses 9 to 20, wherein the D4 is within an interval 1.1×D1<D4<D3.

Clause 22: The multi-beam charged particle microscope (1) according to any of the clauses 9 to 21, further comprising a second absorber plate (371.2), the second absorber plate (371.2) being arranged between the filter plate (304) and the shielding multi-aperture plate (306).

Clause 23: The multi-beam charged particle microscope (1) according to any of the clauses 9 to 22, further comprising
a first collector lens (315.1, 315.2);
the absorber plate (371) with a plurality of apertures (85.4) arranged at a first pitch P1, configured for generating during use a plurality of preformed beamlets (312) with the first pitch P1, the absorber plate (371) being arranged between the first collector lens (315) and the at least one collimator lens (303.1, 303.2),
the apertures (85.1) of the filter plate (304) being arranged at a second pitch P2, the second pitch P2 being different from the first pitch P1,
   wherein
the control unit (830 is configured to provide during use a first control signal to the first collector lens (315.1, 315.2) to adjust a current of the plurality of primary charged particle beamlet (3) and configured to provide a second control signal to the at least one collimator lens (303.1, 303.2) to match the pitch P1 of the plurality of preformed beamlets (312) with the second pitch P2 of the filter plate (304) and to adjust the propagation angles of the plurality of preformed beamlets (312) to form parallel preformed beamlets (312).

Clause 24: A multi-beam forming unit (305), comprising
a filter plate (304) with apertures (85.1) with a first diameter D1, the filter plate (304) having a first thickness L1,
a shielding multi-aperture plate (306) with apertures (85.2) with a second diameter D2, the shielding multi-aperture plate (306) arranged at a distance L2 from the filter plate (304) and having a third thickness L3,
an active array-optical element (307) with a plurality of electrodes (81, 82) arrange in vicinity of a plurality of apertures (85.3) with a third diameter D3, arranged downstream of the shielding multi-aperture plate (306),
   wherein the distance L2, the thickness L1 and the second diameter D2 fulfill the following: D2/(L1+L2)<=0.3, such as <0.25.

Clause 25: The multi-beam forming unit (305) according to clause 24, wherein the distance L2, the thicknesses L1 and L3 and the second diameter D2 are selected according to D2/(L1+L2)<=0.3, such as <0.25.

Clause 26: The multi-beam forming unit (305) according to clause 24 or 25, wherein D3 is selected according D3>=D2>D1.

Clause 27: The multi-beam forming unit (305) according to any of the clauses 24 to 26, wherein D2 is selected according 1.1×D1<D2<1.3×D1.

Clause 28: The multi-beam forming unit (305) according to any of the clauses 24 to 27, wherein (L1+L2+L3)>130 μm, such as >150 μm.

Clause 29: The multi-beam forming unit (305) according to any of the clauses 24 to 28, wherein within each of the apertures (85.2) of the shielding multi-aperture plate (306), at least one baffle (369) is formed.

Clause 30: The multi-beam forming unit (305) according to any of the clauses 24 to 29, wherein within each of the apertures (85.2) of the shielding multi-aperture plate (306), an aperture of diameter D2 is formed with a thickness L3.1<U.

Clause 31: The multi-beam forming unit (305) according to any of the clauses 24 to 30, wherein within each of the apertures (85) of the shielding multi-aperture plate (306), an aperture is formed with a conic shape (365).

Clause 32: The multi-beam forming unit (305) according to clause 31, wherein the minimum aperture diameter D2 is formed at the bottom or beam exit side of the shielding multi-aperture plate (306).

Clause 33: The multi-beam forming unit (305) according to clause 31, wherein the minimum aperture diameter D2 is formed at the upper or beam entry side of the shielding multi-aperture plate (306).

Clause 34: The multi-beam forming unit (305) according to any of the clauses 24 to 33, wherein the shielding multi-aperture plate (306) is provided with at least one conductive layer (361) at the upper or beam entry side of the shielding multi-aperture plate (306).

Clause 35: The multi-beam forming unit (305) according to clause 34, wherein the at least one conductive layer (361) is one of a metal layer, a graphite layer, or a doped semiconductor layer.

Clause 36: The multi-beam forming unit (305) according to any of the clauses 24 to 35, wherein the shielding multi-aperture plate (306) comprises a material of a group of materials comprising Molybdenum, Ruthenium, Rhodium, Palladium or Silver, Tungsten, Rhenium, Osmium, Iridium, Platinum, or Gold.

Clause 37: The multi-beam forming unit (305) according to any of the clauses 24 to 36, further comprising a first absorber plate (371, 371.1) with a plurality of apertures (85.4) with a diameter D4, wherein 1.1×D1<D4<D3.

Clause 38: The multi-beam forming unit (305) according to clause 37, wherein the first absorber plate (371, 371.1) is arranged between the filter plate (304) and the shielding multi-aperture plate (306).

Clause 39: The multi-beam forming unit (305) according to clause 37, wherein the first absorber plate (371, 371.1) is arranged upstream of the filter plate (304).

Clause 40: The multi-beam forming unit (305) according to any of the clauses 24 to 39, further comprising a second absorber plate (371.2), the second absorber plate (371.2) being arranged between the filter plate (304) and the shielding multi-aperture plate (306).

Clause 41: A multi-beam forming unit (305), comprising
a filter plate (304) with apertures (85.1) with a first diameter D1, the filter plate (304) having a first thickness L1;
a shielding multi-aperture plate (306) with apertures (85.2) with a second diameter D2, the shielding multi-aperture plate (306) having a third thickness L3;
a active array-optical element (307) with a plurality of electrodes (81, 82) arrange in vicinity of a plurality of apertures (85.3) with diameter D3, the active array-optical element (307) having a thickness of L5;
   wherein 1.1×D1<D2<=1.3×D1.

Clause 42: The multi-beam forming unit (305) according to clause 41, wherein within each of the apertures (85.2) of the shielding multi-aperture plate (306), a plurality of baffles (369) are formed.

Clause 43: The multi-beam forming unit (305) according to clause 41 or 42, wherein within each of the apertures (85.2) of the shielding multi-aperture plate (306), an aperture of diameter D2 is formed with a thickness L3.1<L3.

Clause 44: The multi-beam forming unit (305) according to clause 41, wherein within each of the apertures (85.2) of the shielding multi-aperture plate (306), an aperture is formed with a conic shape (365).

Clause 45: The multi-beam forming unit (305) according to clause 44, wherein the minimum aperture diameter D2 is formed at the bottom or beam exit side of the shielding multi-aperture plate (306).

Clause 46: The multi-beam forming unit (305) according to clause 44, wherein the minimum aperture diameter D2 is formed at the upper or beam entry side of the shielding multi-aperture plate (306).

Clause 47: The multi-beam forming unit (305) according to any of the clauses 41 to 46, wherein the shielding multi-aperture plate (306) is provided with at least one conductive layer (361) at the upper or beam entry side of the shielding multi-aperture plate (306).

Clause 48: The multi-beam forming unit (305) according to clause 47, wherein the at least one conductive layer (361) is one of a metal layer, a graphite layer, or a doped semiconductor layer.

Clause 49: The multi-beam forming unit (305) according to any of the clauses 41 to 46, wherein the shielding multi-aperture plate (306) comprises a material of a group of materials comprising Molybdenum, Ruthenium, Rhodium, Palladium or Silver, Tungsten, Rhenium, Osmium, Iridium, Platinum, or Gold.

Clause 50: The multi-beam forming unit (305) according to any of the clauses 41 to 49, further comprising a first absorber plate (371, 371.1) with a plurality of apertures (85.4) with a diameter D4, wherein 1.1×D1<D4<D3.

Clause 51: The multi-beam forming unit (305) according to clause 50, wherein the first absorber plate (371, 371.1) is arranged between the filter plate (304) and the shielding multi-aperture plate (306).

Clause 52: The multi-beam forming unit (305) according to clause 50, wherein the first absorber plate (371, 371.1) is arranged upstream of the filter plate (304).

Clause 53: The multi-beam forming unit (305) according to clause 52, further comprising a second absorber plate (371.2), the second absorber plate (371.2) being arranged between the filter plate (304) and the shielding multi-aperture plate (306).

Clause 54: A multi-beam forming unit (305), comprising
a filter plate (304) with apertures (85.1) with a first diameter D1, the filter plate (304) having a first thickness L1;
a active array-optical element (307) with a plurality of electrodes (81, 82) arrange in vicinity of a plurality of apertures (85.3) with diameter D3, the active array-optical element (307) having a thickness of L5;
a first absorber plate (371, 371.1) with a plurality of apertures (85) with a diameter D4, wherein 1.1×D1<D4<D3.

Clause 55: The multi-beam forming unit (305) according to clause 54, wherein the first absorber plate (371, 371.1) is arranged between the filter plate (304) and the first array optical element (306.2).

Clause 56: The multi-beam forming unit (305) according to clause 54, wherein the first absorber plate (371, 371.1) is arranged upstream of the filter plate (304).

Clause 57: The multi-beam forming unit (305) according to any of the clauses 54 to 56, wherein within at least one of the apertures (85.4) of the first absorber plate (371, 371.1), a plurality of baffles (369) are formed.

Clause 58: The multi-beam forming unit (305) according to any of the clauses 54 to 57, wherein within at least one of the apertures (85.4) of the first absorber plate (371, 371.1), an aperture of diameter D4 is formed with a thickness LX.1<LX.

Clause 59: The multi-beam forming unit (305) according to any of the clauses 54 to 68, wherein within at least one of the apertures (85.4) of the first absorber plate (371, 371.1), an aperture is formed with a conic shape (365).

Clause 60: The multi-beam forming unit (305) according to clause 59, wherein the minimum aperture diameter D4 is formed at the bottom or beam exit side of the first absorber plate (371, 371.1).

Clause 61: The multi-beam forming unit (305) according to clause 59, wherein the minimum aperture diameter D4 is formed at the upper or beam entry side of the first absorber plate (371, 371.1).

Clause 62: The multi-beam forming unit (305) according to any of the clauses 54 to 61, wherein the first absorber plate (371, 371.1) is provided with at least one conductive layer (361) at the upper or beam entry side of the first absorber plate (371, 371.1).

Clause 63: The multi-beam forming unit (305) according to clause 62, wherein the at least one conductive layer (361) is one of a metal layer, a graphite layer, or a doped semiconductor layer.

Clause 64: The multi-beam forming unit (305) according to any of the clauses 54 to 63, wherein the first absorber plate (371, 371.1) comprises a material of a group of materials comprising Molybdenum, Ruthenium, Rhodium, Palladium or Silver, Tungsten, Rhenium, Osmium, Iridium, Platinum, or Gold.

Clause 65: The multi-beam forming unit (305) according to any of the clauses 56 to 64, further comprising a second absorber plate (371.2), the second absorber plate (371.2) being arranged between the filter plate (304) and the first array optical element (306.2).

Clause 66: A multi-beam charged particle microscope (1), comprising a multi-beam forming unit (305) according to any of the clauses 24 to 65.

Clause 67: A multi-beam generating unit (300) for generating a plurality of primary charged particle beamlets (3), comprising
a source of charged particles (301);
a first collector lens (315) for collecting and forming a primary charge particle beam (309);
a absorber plate (371) with a plurality of apertures (85.4) arranged at a first pitch P1, configured for generating during use a plurality of preformed beamlets (312) with the first pitch P1;
a collimator lens (303);
a multi-beam forming unit (305) with a filter plate (304) with apertures (85.1) arranged at a second pitch P2,
a control unit (830), wherein
the control unit (830) is configured to provide during use a first control signal to the first collector lens (315) to adjust a current of the plurality of primary charged particle beamlet (3) and configured to provide a second control signal to the collimator lens (303) to match the pitch P1 of the plurality of preformed beamlets (312) with the second pitch P2 of the filter plate (304) and to adjust the propagation angles of the plurality of preformed beamlets (312) to form parallel preformed beamlets (312).

Clause 68: A multi-beam charged particle microscope (1), comprising a multi-beam generating unit (300) according to clause 67.

Clause 69: A multi-beam charged particle microscope (1), further comprising a multi-beam forming unit (305) according to any of the clauses 24 to 65.

The described embodiments and example of the disclosure can be combined with one another in full or in part, provided that no technical contradictions arise as a result. The disclosure is also not restricted to the specific embodiments, examples, and combinations thereof, but variations of the embodiments are also possible. For example, the material compositions and structure or the shielding plate (306) or absorber plate (371) can also be applied to the filter plate (304), and the filter plate can be made of a metal or metal composition comprising at least one metal selected from the group of Molybdenum, Ruthenium, Rhodium, Palladium or Silver, Tungsten, Rhenium, Osmium, Iridium, Platinum, or Gold. Thereby, the stopping power for x-rays is increased. The cover layer (99) or the filter plate (304) can be made from a conductive material of low atomic mass and can be realized as for example a graphite layer or a highly doped semiconductor layer, or a metal layer comprising a metal of lower atomic mass, for example aluminum, manganese, copper or silver. Thereby, the generation of secondary electrons is reduced.

Although in principle reference is made to a wafer as an object, the disclosure is also applicable to other objects as used in semiconductor manufacturing. By way of example, the object can also be a mask, for example a mask for EUV lithography, rather than a semiconductor wafer. In contrast to semiconductor wafers, such masks are generally rectangular and have a significantly greater thickness. The disclosure is however not limited to objects as used in semiconductor manufacturing, but is also applicable to general objects, including for example mineral probes or tissue. The disclosure is further described at the example of a multi-beam system having a plurality of primary electron beamlets, but other charged particles, for example helium ions, may also be used.

A list of reference signs is provided:
1 multi-beamlet charged-particle microscopy system
3 primary charged particle beamlets
5 focus spot of primary charged particle beamlet
7 object
9 secondary electron beamlets
15 focus spot of secondary electron beamlet
25 Wafer surface
81 multipole electrodes
82 annular electrode
83 Spacers
85 apertures
86 spacer
92 electrostatic fields (equipotential lines)
94 terminating apertures
98 layer of a conductive material
99 absorbing and conductive layer
100 object irradiation unit
101 object plane
102 objective lens
103 field lens group
108 first beam cross over
110 collective multi-beam raster scanner
200 secondary electron imaging system
205 electron-optical elements
216 multi-aperture corrector
222 second deflection system
225 image plane
261 Voltage Supply lines
300 charged-particle multi-beamlet generator
301 charged particle source
303 collimating lenses
304 filter plate
305 primary multi-beamlet-forming unit
306 shielding multi-aperture plate
307 active array-optical element
308 field lens
309 primary electron beam
310 terminating multi-aperture plate
311 focus spots of primary charged particle beamlets
312 preformed beamlets
313 beam deflector
315 collecting lens
317 intersection point
319 Scattering point
321 intermediate image surface
323 Intermediate image plane tilt component
351 X-ray radiation
353 secondary electrons
355 transmitted charged particle
359 scattered charged particle
361 conducting layer
363 isolating layer
365 inclined edge
367 bulk structure
369 baffles
371 absorber plate
391 first layer
392 second layer
393 electrode layer
394 fourth layer
395 fifth layer
400 beam splitter unit
500 sample stage
503 Sample voltage supply
600 detector
800 control unit
810 imaging control module
830 multi-beam forming control unit
860 Scanning control unit
880 Control processor
890 Memory

What is claimed is:

1. A method, comprising:
using multi-beam forming unit of a multi-beam charged particle microscope to generate a primary charged particle beam;
providing:
i) a first voltage to a filter plate comprising a plurality of apertures so that the plurality of apertures form and transmit a plurality of primary charged particle beamlets from the primary charged particle beam, the primary charged particle beam generating secondary electrons at intersection points of primary electrons of the primary charged particle beam with the filter plate; or
ii) a plurality of individual fourth voltages to a plurality of electrodes of an active array-optical element, the electrodes being arranged in a vicinity of a plurality of apertures of an active array-optical element, so that each electrode focuses, deflect or shape a primary charged particle beamlet;
providing: a) a second voltage to a second multi-aperture plate disposed between the filter plate and the active array-optical element; or b) an absorber plate voltage to an absorber plate disposed in a propagation direction of the primary charged particle beam upstream of the filter plate; and
adjusting at least one member selected from the group consisting of the absorber plate voltage, the first voltage, and the second voltage, thereby preventing secondary electrons from intersecting with the active array-optical element by either achieving a potential barrier for the secondary electrons or a potential sink for the secondary electrons.

2. The method of claim 1, comprising adjusting the second voltage to be less than the first voltage to achieve either a potential barrier for the secondary electrons upstream of the second multi-aperture plate or a potential sink for the secondary electrons upstream of the second multi-aperture plate.

3. The method of claim 1, comprising adjusting the second voltage to be greater than the first voltage to achieve a potential sink for the secondary electrons in a proximity of the second multi-aperture plate.

4. The method of claim 1, comprising adjusting the absorber plate voltage to be greater than the first voltage to achieve a potential sink for the secondary electrons upstream of the filter plate.

5. The method of claim 1, wherein at least one member selected from the group consisting of the absorber plate voltage, the first voltage, and the second voltage is at a ground or reference level.

6. The method of claim 1, further comprising providing a third voltage to a first layer of the active array-optical element, wherein the third voltage is equal to the first voltage or the second voltage.

7. The method of claim 1, further comprising providing a fifth voltage to a fifth layer of the active array-optical element, wherein the fifth voltage is equal to the first voltage or the second voltage.

8. One or more machine-readable hardware storage devices comprising instructions that are executable by one or more processing devices to perform operations comprising the method of claim 1.

9. A system, comprising:
one or more processing devices; and
one or more machine-readable hardware storage devices comprising instructions that are executable by one or more processing devices to perform operations comprising the method of claim 1.

10. A multi-beam charged particle microscope, comprising:
a charged particle source and a condenser lens configured to generate and form a primary charged particle beam;
a multi-beam forming unit, comprising:
a filter plate comprising a plurality of apertures with a diameter configured to form a plurality of primary charged particle beamlets;
an active array-optical element comprising a plurality of apertures with a third diameter, the active array-optical element configured to individually focus, deflect or shape at least one of the primary charged particle beamlets;
at least one of member selected from the group consisting of: i) a second multi-aperture plate comprising apertures with a second diameter, the second multi-aperture plate being between the filter plate and the active array-optical element; and ii) an absorber plate comprising a plurality of apertures with a diameter, the absorber plate upstream of the filter plate along a propagation direction of the primary charged particle beam; and
a control unit configured to adjust and provide a first voltage to the filter plate, a second voltage to a second multi-aperture plate, or an absorber plate voltage to an absorber plate, thereby preventing secondary electrons generated at the filter plate from intersecting with the active array-optical element by either achieving a potential barrier for the secondary electrons upstream of the active array-optical element or a potential sink for the secondary electrons upstream of the active array-optical element.

11. The multi-beam charged particle microscope of claim 10, wherein:
the filter plate has a thickness L1 that is less than 20 micrometers; and
the second multi-aperture plate is a distance L2 from the filter plate so that D2/(L1+L2)≤0.3, where D2 is the second diameter.

12. The multi-beam charged particle microscope of claim 10, wherein:
the filter plate has a that is less than 20 micrometers; and
the second multi-aperture plate is a distance L2 from the filter plate;
the second multi-aperture plate has a thickness 13; and
D2/(L1+L2+L3)≤0.3, where D2 is the second diameter.

13. The multi-beam charged particle microscope, wherein:
$$D 3 \geq D 2 > D 1 ,$$
where D3 is the third diameter, D2 is the second diameter, and D1 is the diameter of the apertures of the filter plate.

14. The multi-beam charged particle microscope of claim 13, wherein:
$$1.1 \times D 1 < D 2 < 1.3 \times D 1.$$

15. The multi-beam charged particle microscope of claim 12, wherein:
$$( L 1 + L 2 + L 3 ) > 130 microns .$$

16. The multi-beam charged particle microscope of claim 10, further comprising a plurality of baffles, each baffle being within a corresponding aperture of the second multi-aperture plate.

17. The multi-beam charged particle microscope of claim 10, further comprising, within each aperture of the second multi-aperture plate, an aperture having the second diameter and a thickness that is less than a thickness of the second multi-aperture plate.

18. The multi-beam charged particle microscope of claim 10, wherein each aperture of the second multi-aperture plate has a conic shape.

19. The multi-beam charged particle microscope of claim 18, wherein a minimum aperture of the conic shape is at a beam exit side of the second multi-aperture plate.

20. The multi-beam charged particle microscope of claim 18, wherein a minimum aperture diameter at a beam entry side of the second multi-aperture plate.

21. The multi-beam charged particle microscope of claim 10, wherein the second multi-aperture plate comprises a metal layer at a beam entry side of the second multi-aperture plate.

22. The multi-beam charged particle microscope of claim 10, wherein:
$$1.1 \times D 1 < D 4 < D 3 ,$$
where D1 is the diameter of the apertures of the filter plate, D4 is the diameter of the apertures of the absorber plate, and D3 is the third diameter.

23. The multi-beam charged particle microscope of claim 10, further comprising a second absorber plate between the filter plate and the shielding multi-aperture plate.

24. The multi-beam charged particle microscope of claim 10, further comprising a first collector lens, wherein:
the apertures of the absorber plate have a first pitch and are configured to generate a plurality of preformed beamlets with the first pitch;
the absorber plate is between the first collector lens and the collimator lens;
the apertures of the filter plate have a second pitch different from the first pitch;
the control unit is configured to provide: i) a first control signal to the first collector lens to adjust a current of the plurality of primary charged particle beamlets; and ii) a second control signal to the collimator lens to match the first and second pitches to adjust the propagation angles of the plurality of preformed beamlets to form parallel preformed beamlets.
